(19) United States
(12) Patent Application Publication
(10) Pub. No.: US 2018/0013023 A1
(43) Pub. Date: Jan. 11, 2018

(54) SHADE MANAGEMENT OF SOLAR CELLS AND SOLAR CELL REGIONS

(71) Applicant: OB REALTY, LLC, Irvine, CA (US)

(72) Inventor: MEHRDAD M. MOSLEHI, Los Altos, CA (US)

(21) Appl. No.: 15/547,719

(22) PCT Filed: Feb. 1, 2016
(86) PCT No.: PCT/US2016/016025

§ 371 Date: Jul. 31, 2017

Related U.S. Application Data
(60) Provisional application No. 62/110,387, filed on Jan. 30, 2015.
(60) Provisional application No. 62/111,652, filed on Feb. 3, 2015.
(60) Provisional application No. 62/117,418, filed on Feb. 17, 2015.
(60) Provisional application No. 62/164,992, filed on May 21, 2015.
(60) Provisional application No. 62/190,235, filed on Jul. 8, 2015.
(60) Provisional application No. 62/202,776, filed on Aug. 7, 2015.

(51) Int. Cl. H01L 31/044; H01L 31/05; H01L 31/068

(52) U.S. Cl. CPC H01L 31/044; H01L 31/0682; H01L 31/0516; Y02E 10/50

(57) ABSTRACT

A photovoltaic solar structure comprises at least two electrically connected solar cell regions forming a shade management block. The solar cell regions have a light receiving frontside and a passivated backside opposite the light receiving frontside and a first metallization over the passivated backside has base and emitter metallization contacting base and emitter regions of the solar cell regions. An electrically insulating backplane is over the backsides of the two solar cells regions. The electrically insulating backplane covers the first metallization of the two solar cell regions. A second metallization is over the electrically insulating backplane and contacts the first metallization through the electrically insulating backplane. The second metallization has at least an opposite polarity electrical connection electrically connecting the solar cell regions of the shade management block. The opposite polarity connection has positive and negative electrical polarities. The opposite polarity electrical connection is connected to a bypass diode.

### CROSS-REFERENCE TO RELATED APPLICATIONS

This application claims the benefit of U.S. provisional patent applications 62/110,387 filed Jan. 30, 2015, 62/111,652 filed Feb. 2, 2015, 62/117,418 filed Feb. 17, 2015, 62/164,992 filed May 21, 2015, 62/190,235 filed Jul. 8, 2015, and 62/202,776 filed Aug. 7, 2015, all of which are hereby incorporated by reference in their entirety.

### FIELD OF THE INVENTION

The present disclosure relates in general to the fields of photovoltaic (PV) solar cells.

### BACKGROUND

Increasingly, solar cells and solar modules are looking to solutions to increase efficiency and total electricity generation (energy yield) in shaded or non-optimal light conditions in order to maximize power harvest. Typically, in the case of solar cells connected in series, a shaded or otherwise lower functioning solar cell may dictate and limit the power production for all of the series connected cells—thus resulting in lost photovoltaic (PV) power harvest from the non-shaded or stronger functioning series connected cells.

Additionally, solar cell fabrication and structural complexity often leads to low manufacturing yield and field based solar cell and module failures. Further, installation complexity relating to current flow, wires, and electronic components may further exacerbate solar cell and module failures, compromise reliability, and may result in reduction of PV power harvest.

### BRIEF SUMMARY OF THE INVENTION

Therefore, a need has arisen for a solar cell structure having improved shade management, efficiency, and reduced fabrication complexity. In accordance with the disclosed subject matter, solar cell structures are provided which may substantially eliminate or reduce disadvantages and deficiencies associated with previously developed solar cell structures.

According to one aspect of the disclosed subject matter, a photovoltaic solar structure comprising at least two electrically connected solar cell regions forming a shade management block is provided. The solar cell regions have a light receiving frontside and a passivated backside opposite the light receiving frontside and a first metallization over the passivated backside has base and emitter metallization contacting base and emitter regions of the solar cell regions. An electrically insulating backplane is over the backsides of the two solar cells regions. The electrically insulating backplane covers the first metallization of the two solar cell regions. A second metallization is over the electrically insulating backplane and contacts the first metallization through the electrically insulating backplane. The second metallization has at least an opposite polarity electrical connection electrically connecting the solar cell regions of the shade management block. The opposite polarity connection has positive and negative electrical polarities. The opposite polarity electrical connection is connected to a bypass diode.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is drawing of the backside of an interdigitated back contact back junction solar cell;

FIG. 2 is drawing of the backside of a solar cell showing a second level metallization on a supporting electrically insulating backplane;

FIG. 3 is drawing of the backside of a solar cell showing a second level metallization on a supporting electrically insulating backplane;

FIGS. 4A and 4B are selected cross-sectional diagrams of portions of a back-contact solar cell;

FIG. 5 is a drawing of the backside and second level metallization of a shade management block;

FIG. 6 is a drawing of the backside and second level metallization of a shade management block;

FIGS. 7, 8A, and 8B are drawings of the backside and second level busbar metallization of representative shade management blocks;

FIG. 9 is a representative schematic plan view (frontside or sunnyside view) diagram of an iCell (or monolithically isled cell);

FIGS. 10A and 10B are representative schematic cross-sectional view diagrams of a backplane-attached solar cell;

FIG. 10C is a high level monolithic isled solar cell and module fabrication process flow;

FIGS. 11A, 11B, and 11C are drawings of backplane-attached solar cell (iCell) embodiments;

FIGS. 12A, 12B, and 12C are drawings of backplane-attached solar cell (iCell) embodiments;

FIGS. 13A and 13B are drawings of the backside and second level busbar metallization;

FIGS. 14 and 15 are drawings of the backside and second level busbar metallization of shade management blocks;

FIGS. 16A is a drawing of the backside and second level busbar metallization of a 2×6 monolithically isled solar cell;

FIG. 16B is a drawing showing the 2×6 monolithically isled solar cell of FIG. 16A forming two shade management blocks;

FIG. 17 is a drawing of the backside and second level busbar metallization of a 2×6 monolithically isled solar cell forming a shade management block;

FIG. 18 is a drawing of the backside and second level busbar metallization of a 2×6 monolithically isled solar cell forming two shade management blocks;

FIG. 19 is a drawing of the backside and second level busbar metallization of two 2×6 monolithically isled solar cells forming four shade management blocks;

FIG. 20A is drawing of the backside and second level busbar metallization of a 1×10 monolithically isled solar cell with an optional vertical y-axis mechanical trench isolation region;

FIG. 20B is drawing of the backside and second level busbar metallization of a 1×10 monolithically isled solar cell with an optional vertical y-axis mechanical trench isolation region and showing solar isle base to emitter electrical connection;

FIG. 21 is drawing of the backside and second level busbar metallization of a 1×10 monolithically isled solar cell forming three shade management blocks;

FIG. 22 is drawing of the backside and second level busbar metallization of a 1×10 monolithically isled solar cell forming two shade management blocks;

FIG. 23A is drawing of the backside and second level busbar metallization of a 1×6 monolithically isled solar cell with an optional vertical y-axis mechanical trench isolation region;

FIG. 23B is drawing of the backside and second level busbar metallization of a 1×6 monolithically isled solar cell with an optional vertical y-axis mechanical trench isolation region and showing solar isle base to emitter connection;

FIG. 24 is drawing of the backside and second level busbar metallization of a 1×6 monolithically isled solar cell with an optional vertical y-axis mechanical trench isolation region and forming three shade management blocks;

FIG. 25 is drawing of the backside and second level busbar metallization of a 1×6 monolithically isled solar cell forming three shade management blocks; and

FIG. 26 is drawing of the backside and second level busbar metallization of a 1×6 monolithically isled solar cell forming two shade management blocks.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to specific embodiments and components, one skilled in the art could apply the principles discussed herein to other solar cell structures (e.g., back contact back junction solar cells, back contact front junction solar cells or emitter wrap through solar cells) and materials (e.g., monocrystalline or multi-crystalline silicon and III-V semiconductors such as gallium arsenide), fabrication processes (e.g., various deposition methods and materials such as metallization materials), as well as alternative technical areas and/or embodiments without undue experimentation.

Importantly, the drawings provided depicting aspects of metallization patterns and solar cell cross-sections are not drawn to scale. Additionally, the metallization diagrams shown presented for descriptive purposes and may have different x and y axis scales. The following are provided as exemplary dimensional embodiments, however individual solar cells, metallization materials, and various requirements may dictate continuous backplane and metallization pattern dimensions.

Photovoltaic (PV) solar cell structures and fabrication methods providing electrical power and shade management solutions are described. These comprehensive solar cell solutions may be characterized by integrated solar cell metallization and solar cell electronics forming shade management blocks of solar cells or solar cell regions. Solar cell structures and fabrication methods may also scale cell current and voltage as desired (e.g., decrease current and increase voltage for lower ohmic losses). The solar cell structures and fabrication methods solutions described provide improved manufacturability as well as increased shade management (shade tolerance) design flexibility.

As described herein, a shade management (also meaning shade tolerance) block may be a whole solar cell, portions of a solar cell, a combination of solar cells, a combination of portions of adjacent solar cells, or combinations thereof. Therefore, for descriptive purposes the term solar cell is used in relation to a solar cell region having base and emitter metallization with opposite electrical polarities (e.g., negative base and positive emitter). Solar cell electronics refers to a power bypass structure such as a bypass diode (e.g., a bypass rectifying diode such as Schottky Barrier Rectifier SBR, or a PN junction diode, or a transistor bypass switch). The bypass diode acts as a switch to bypass the solar cells or solar regions of the shade management block in the case of reduced solar cell electrical power production or current mismatch with the rest of the series-connected string of shade management blocks, for example due to low light irradiation (such as due to localized shading of certain regions of the PV module) or failure of a solar cell in the shade management building block.

The solar cell electronics may also have solar cell power optimizers such as an MPPT (Maximum-Power-Point-Tracking) power optimizer or a DC power optimizer for enhanced solar cell shade management—for example, a bypass diode (e.g., an SBR) and MPPT power optimizer chip such that the bypass diode is connected as an out-put stage SBR at the output of the MPPT power optimizer (as well as SBRs within each shade management block). A power optimizer may provide maximum power point tracking (MPPT) for each shade management building block. Thus, each shade management block may have at least one shade management bypass diode and one MPPT power optimizer chip.

Key solar cell and solar region structure and material considerations include electrical conductivity (or electrical resistivity) and metal-related ohmic losses, for example due to current flow and I²R ohmic losses. Additionally, solar cell electronics, such as bypass diodes, operate under current constraints which typically increase in complexity and/or cost (and package size and thermal dissipation losses) corresponding to an increase in solar cell current. To reduce solar cell current, and thus relax metallization requirements (e.g., reduced cell metal thickness and production cost) and size & cost of solar cell electronics, without reducing solar cell power production, monolithically isled solar cells are provided. Additionally, solar cell structure having a backplane supported two level metallization structure (e.g., comprising a first metallization, first metal layer/level, or M1 and a second metallization, second metal layer/level, M2 contacting M1 through an electrically insulating backplane) allows for flexibility to design and provide shade management blocks and flexibility to connect/interconnect shade management blocks. Structures and methods for forming isled solar cells having integrated backplane supported dual level metallization structure referred to as an iCell or monolithically isled solar cell may be found in related U.S. Patent Pub. 2014/0370650 published Dec. 18, 2014, which is hereby incorporated by reference in its entirety.

The present application provides effective and efficient solar solutions having substantially improved fabrication method and photovoltaic structure advantages. The novel solar cell and metallization structures described herein utilize a multi-layer metallization structure, such as a two-level metallization structure, comprising a first metallization (M1) of base and emitter metallization and a second metallization (M2) collecting power (voltage and current) from the first metallization M1 (hence, completing the solar cell metallization) and also forming cell to cell connections. The second metallization M2 may comprise an interdigitated pattern of base and emitter current collection fingers and optionally solar cell base and emitter busbars. The first metallization (M1) may comprise an interdigitated back contact metallization structure with a relatively fine pitch (much finer pitch than the second metallization M2 pitch), and advantageously may be orthogonal/perpendicular to the interdigitated fingers of M2 (parallel M1/M2 fingers also may be suitable in some instances). A continuous electrically insulating backplane, which may be relatively thin, formed between M1 and M2 and attached to the solar cells provides solar cell structural support, M1 electrical insulation, and allows for solar cell fabrication (particularly M2 fabrication and solar cell frontside processing) processing improvement. The solar cell and region embodiments provided herein utilize a continuous backplane sheet, preferably a flexible material closely CTE-matched with the solar cell semiconductor substrate material (e.g., crystalline silicon for silicon solar cells), laminated or otherwise attached to solar cells or regions, for example a plurality of back-contact back-junction solar cells or regions, prior to completion of the remaining solar cell manufacturing process steps. For example, the laminated backplane embodiments provided herein allow for variable readily adaptable M2 metallization patterning and provide solar cell backside and in some instances may also provide M1 protection during subsequent processing—key advantages in plasma deposition processing, thermal processing, and/or wet chemistry processing steps for the remaining solar cell production steps.

In a multi-level metallization design, for example a two-level metal design comprising a first level metal M1 (for instance, a fine-pitched interdigitated metallization structure comprising aluminum or another suitable metal), and a second level metal M2 (for instance, a coarse-pitched interdigitated metallization structure comprising aluminum or copper or another suitable metal), M1 may comprise interdigitated base and emitter lines (for instance, with base-emitter finger pitch of <2 mm and preferably <1 mm) and M2 (preferably with its fingers substantially orthogonal/perpendicular to M1 fingers and with a much coarser base-emitter pitch compared to M1) serves as the electrical connector among M1 base and emitter lines (i.e., a busbarless M1 pattern while the cell busbars may be placed on the M2 pattern). The metal layers in the disclosed multi-level metal designs are separated by a dielectric or an electrically insulating layer, such as a resin/fiber based prepreg material or alternatively a suitable plastic or polymer based material, forming a continuous backplane for each of the plurality of solar cells in the solar cell array placed on the continuous backplane. Importantly, the continuous backplane should preferably be relatively closely CTE (Coefficient of Thermal Expansion) matched to the CTE of the semiconductor absorber (e.g., crystalline silicon) so as to minimize CTE mismatch stress or warpage effects during thermal processing—for example a specially formulated aramid fiber resin prepreg material provides close CTE matching with silicon while providing flexibility, electrical insulating, thermal and chemical stability, and other desirable processing and reliability characteristics such as effective crack-free lamination. M1/M2 interconnection structures include conductive material filled vias through the insulating layer (e.g., an insulating dielectric layer such as prepreg backplane) positioned between M1 and M2—laminated or attached to the backsides of the solar cells after formation of the patterned M2 layer.

The continuous backplane material attached to the backsides of a plurality of solar cells and placed between patterned M1 and M2 layers may be a thin (e.g., between approximately 25 microns and 1 mm and preferably between approximately 25 microns and 250 microns) sheet of a polymeric material with sufficiently low coefficient of thermal expansion (CTE) which is closely matched to that of the semiconductor absorber layer in order to avoid causing excessive thermally induced stresses and warpage on the solar cell array. Moreover, the backplane material should meet process integration requirements for the backend cell fabrication processes, in particular chemical resistance during wet texturing of the cell frontside and thermal stability during the PECVD deposition of the frontside passivation and anti-reflection coating (ARC) layer. Moreover, the electrically insulating backplane material should also meet the module-level lamination process and long-term reliability requirements. While various suitable polymeric (such as plastics, fluoropolymers, prepregs, etc.) and suitable non-polymeric materials (such as glass, ceramics, etc.) may be used as the backplane material, backplane material choice depends on many considerations including, but not limited to, material cost, ease of process integration, reliability, pliability, mass density, etc.

A preferable material choice for the backplane material is prepreg and more particularly an aramid fiber resin based prepreg (or even a glass fiber prepreg). In some instances, a non-woven aramid fiber is particularly advantageous. Prepreg sheets are used as building blocks of printed circuit boards and may be made from combinations of resins and CTE-reducing fibers or particles. The backplane material may be an inexpensive, low-CTE (typically with CTE <25 ppm/° C., or preferably with CTE <10 ppm/° C.), thin (for example 25 to 250 microns, and more particularly in the range of about 50 to 150 microns) prepreg sheet which is relatively chemically resistant to texturization chemicals and is thermally stable at temperatures up to at least 180° C. (or preferably at least about 250° C., in non-oxidizing ambient). Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure. Conventional prepregs are formulated for autoclave curing while low-temperature prepregs may be fully cured by using vacuum bag pressure alone at much lower temperatures.

The continuous prepreg sheet may be attached to the solar cells backsides using a vacuum laminator. Upon applying a combination of heat and pressure, the thin prepreg sheet is permanently laminated or attached to the backsides of the plurality of partially-processed (or even fully-processed) solar cells. In the case of partially-processed solar cells, subsequent post-lamination fabrication process steps may include: (i) completion of the texture and passivation processes on the sunnysides (frontsides) of the solar cells, (ii) completion of the high conductivity metallization (M2) on the backsides of the solar cells (which may comprise part of the solar cell backplane). The high-conductivity metallization M2 layer (for example comprising aluminum, copper, or silver, with aluminum and/or copper being preferred compared to silver because of much lower material cost) comprising both the emitter and base polarities is formed on the laminated backplane attached to the backsides of the solar cells.

The solar cells described utilize a two level metallization scheme comprising a preferably busbarless (although optional busbars may be used) first-level contact metallization (M1) using a relatively thin patterned metal (e.g., thin aluminum formed by screen printing of an aluminum paste or inkjet printing of an aluminum ink, or alternatively plasma sputtering from an aluminum target followed by laser ablation or wet etch patterning) formed directly on the backside of each solar cell prior to continuous backplane lamination, and a second level thin patterned metal M2 (e.g., comprising approximately 1 to 5 microns thick Al) or alternatively, about 1 to several microns of copper, either case preferably capped with a solderable coating such as tin) formed after continuous backplane lamination to a plurality of solar cells. The patterned M2 layer may also be formed by using plating or lamination and patterning of a high-conductivity metal foil (comprising copper or aluminum). The M1 and M2 layers are separated by the continuous backplane and interconnected at designated regions through conductive via plugs (with the conductive via plugs formed during M2 formation). M1 has fine-pitch pattern and M2 preferably is orthogonal (or substantially perpendicular) to M1 and has coarse pitch pattern (hence, fewer base and emitter fingers compared to M1). Patterned M2 completes both the cell-level and cell array or module-level monolithic electrical interconnections for all the solar cells laminated to the continuous backplane—thus in some instances eliminating the need for separate tabbing/bussing/soldering. Further, M2 may form array/module level bussing or interconnections when desired for array/module electrical interconnection design. The continuous backplane-attached monolithic module (or array of solar cells, for example in some instances a number of solar cell arrays formed in accordance with the disclosed subject matter may be stitched together to make up a larger and higher power solar module—in other words a final end use module may comprise an array, a plurality of arrays, or a fraction of an array of solar cells) may then be laminated either as a frameless flexible and/or lightweight PV module (no cover glass) or as a rigid glass covered PV module.

In some instances, voltage and current scaling (for example, higher voltage and lower current solar cells) relax and reduce M2 conductance requirements and constraints. For example, in consideration with other factors, utilizing a thinner M2 metal (e.g., about 1 to 5 microns thick aluminum or about less than 1 to few microns of copper formed by plasma sputtering or evaporation) as compared to thicker M2 metallization (e.g., about 30 to 80 microns thick electroplated copper). Importantly, the thickness of M1 and M2 metallization layers may also be adjusted based on the number, dimensions, and shape of the interdigitated fingers on the M1 layer and M2 layer. In most applications, it will be preferable that M1 is patterned with finer interdigitated fingers as compared to the interdigitated fingers of M2. However, the cell structures and fabrication embodiments provided are applicable to various dual level metallization schemes utilizing a continuous backplane and M2 metallization layer.

Solar cell current and voltage scaling, particularly in the case of decreasing (scaling down) cell current, may advantageously relax solar cell metallization conductance (and metal thickness) requirements. Fabrication of multiple solar cells on a continuous backplane sheet monolithically may provide decreased fabrication complexity resulting in substantially improved processing throughput, improved product reliability, and reduced solar cell and module manufacturing costs.

A shade management building block may be defined as the building block unit comprising more than a single solar region within its structure for distributed power electronics implementation within the PV module. For example, a shade management block may comprise multiple solar cells or solar regions (e.g., 2, 3, 4 . . . ) within a building block. The number of solar cells or solar regions within a shade management building block may be either an integer or a non-integer (e.g., 1.5, 2, 2.5, 3, etc.). The optimal structure and size of the shade management building block may be chosen based on a wide range of important considerations, including: voltage scaling factor, current scaling factor, shade management block power, cost and performance targets for power electronics, distributed shade management and power harvest granularity, sizing and utilization of string inverter, solar cell and module metallization requirements, metallization materials including cost and conductivity, busbar length including ohmic loss, placement of power electronic parts, product reliability, fault tolerance, etc.

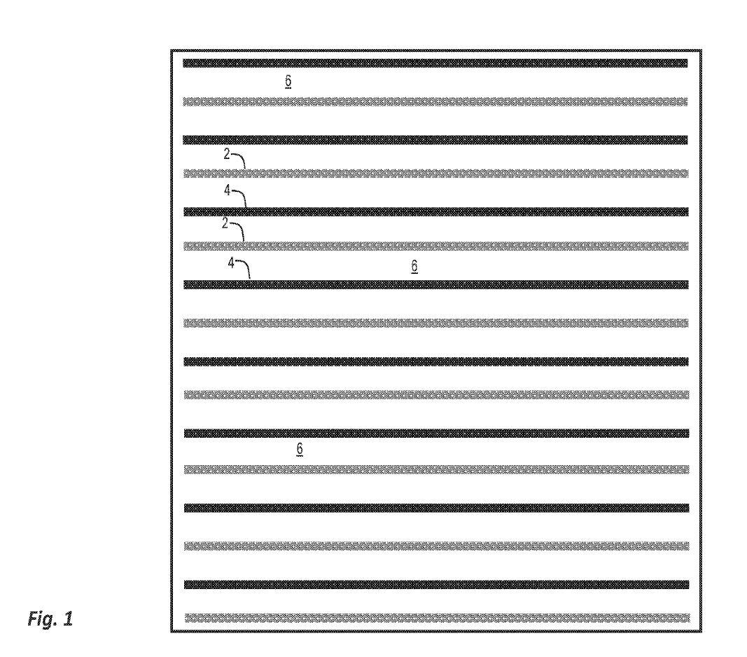

The solar cell regions described have backplane supported two level solar cell metallization. FIG. 1 is drawing of the backside of an interdigitated back contact back junction solar cell showing a first level metallization having an interdigitated base and emitter metallization of base fingers 4 (contacting base regions) and emitter fingers 2 (contacting emitter regions) over the bulk of the back contact solar cell for majority and minority carrier collection. Exposed solar cell backside surface 6 includes the portion of the backside surface not covered by the first level metal. The first level metal base and emitter metallization patterns shown herein may correspond to base and emitter regions of the solar cell (not shown).

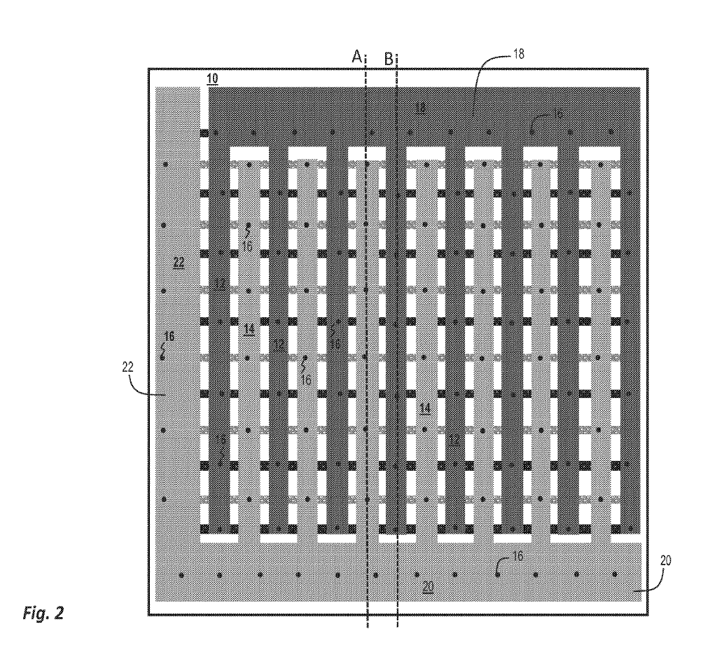

FIG. 2 is drawing of the backside of a solar cell showing a second level metallization on supporting electrically insulating backplane 10 (e.g., a prepreg backplane) and contacting first level metallization of FIG. 1. Although a first level metallization is covered by supporting backplane 10 and thus non-visible, underlying first level metallization (i.e., under supporting backplane 10) is shown in FIG. 2 for descriptive purposes. The second level metallization has an interdigitated pattern of base fingers 12 and emitter fingers 14 and corresponding base and emitter busbars over the supporting backplane and connected to the base and emitter metallization of FIG. 1, respectively, by electrically conductive via plugs 16 (e.g., conductive material in vias through the supporting backplane). Base fingers 12 connect to base fingers 4 and emitter fingers 14 electrically connect to emitter fingers 2. Base fingers 12 and emitter fingers 14 are orthogonally patterned to base fingers 2 (contacting base regions) and emitter fingers 4. Base fingers 12 connect to base busbar 18 and emitter fingers 14 connect to emitter busbar 20. Base busbar 18 is connected to underlying base fingers 4 and emitter busbar 20 is connected to underlying emitter fingers 2 by conductive via plugs 16. Emitter shade management busbar 22 is connected to emitter busbar 20 and underlying emitter fingers by conductive via plugs 16.

Note that although one conductive via 16 is shown for certain first level metal to second level metal electrical connection in the drawings provided, multiple via plugs and/or via size may be adjusted in accordance with electrical connection requirements such as cell current or metallization conductivity.

Importantly, while base fingers 12 and emitter fingers 14 are shown as having a rectangular shape, base fingers 12 and emitter fingers 14 may be designed in a number of geometric or non-geometric designs. Particularly, base fingers 12 and emitter fingers 14 may be tapered with a wider side proximate the fingers corresponding busbar (e.g., base fingers 12 wider proximate base busbar 18 in FIG. 2) to improve current collection efficiency and to reduce the parasitic ohmic losses.

It is to be noted, the interdigitated fingers and busbars of the drawings are not drawn to scale and the dimensions as well as the number of fingers may vary (for example the first level metallization may comprise on the order of hundreds of interdigitated fingers and the second level metallization busbars may have varying width and thickness depending on electric current requirements).

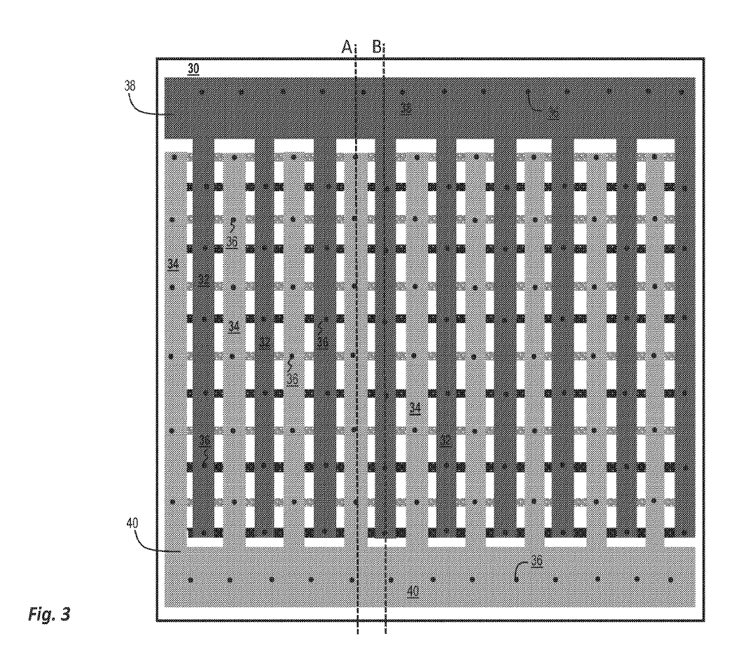

FIG. 3 is drawing of the backside of a solar cell showing a second level metallization on supporting electrically insulating backplane 30 (e.g., a prepreg backplane) and contacting first level metallization of FIG. 1. Although a first level metallization is covered by supporting backplane 30 and thus non-visible, underlying first level metallization (i.e., under supporting backplane 30) is shown in FIG. 3 for descriptive purposes. The second level metallization has an interdigitated pattern of base fingers 32 and emitter fingers 34 and corresponding base and emitter busbars over the supporting backplane and connected to the base and emitter metallization of FIG. 1, respectively, by electrically conductive via plugs 36 (e.g., conductive material in vias through the supporting backplane). Base fingers 32 connect to base fingers 4 and emitter fingers 34 electrically connect to emitter fingers 2. Base fingers 32 and emitter fingers 34 are orthogonally patterned to base fingers 4 (contacting base regions) and emitter fingers 2. Base fingers 32 connect to base busbar 38 and emitter fingers 34 connect to emitter busbar 40. Base busbar 38 is connected to underlying base fingers 4 and emitter busbar 40 is connected to underlying emitter fingers 2 by conductive via plugs 36.

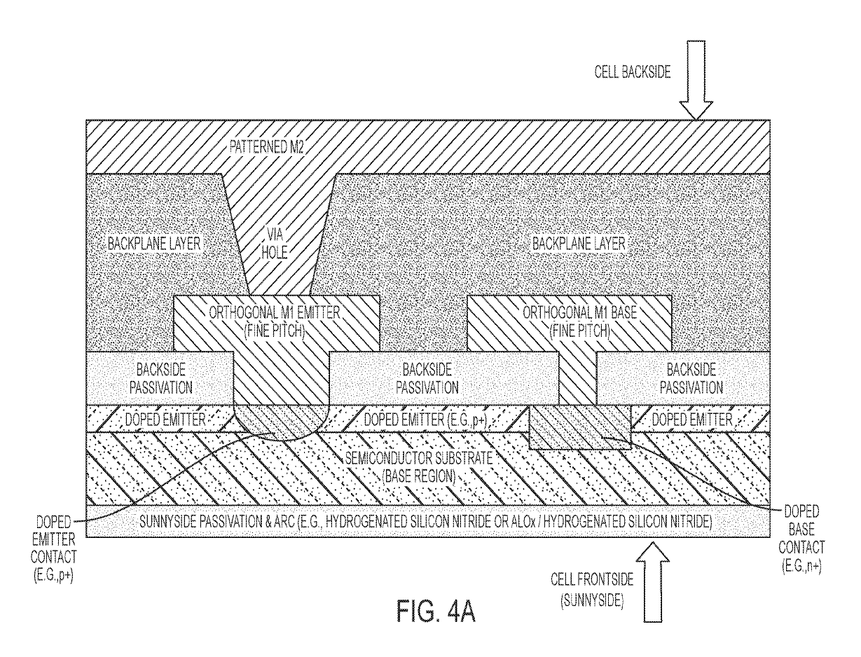

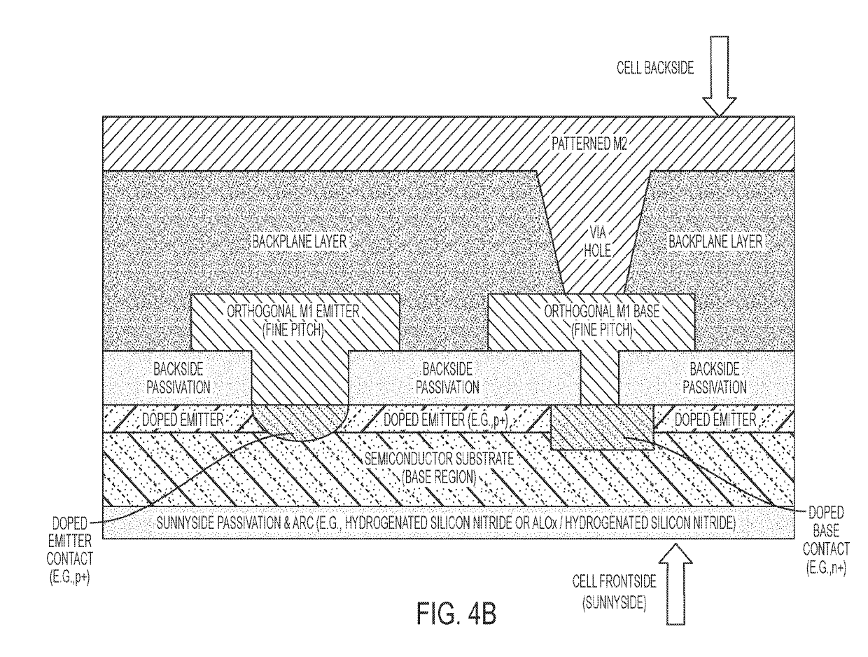

FIGS. 4A and 4B are selected cross-sectional diagrams of portions of a back-contact solar cell along cross-sectional axis showing orthogonal M1/M2 emitter connection and orthogonal M1/M2 base connection, respectively, and are provided as descriptive embodiments to further detail cell architectures which may be used in accordance with the disclosed subject matter. FIG. 4A is a cross-sectional diagram showing a portion of an M1/M2 emitter connection—for example with reference to FIGS. 2 and 3 a cross-sectional along the A axis, with reference to FIG. 2 showing the connection between M1 emitter finger 2 and orthogonal M2 emitter finger 14 by via 16. FIG. 4B is a cross-sectional diagram showing a portion of an M1/M2 base connection—for example with reference to FIGS. 2 and 3 a cross-sectional along the B axis, with reference to FIG. 2 showing the connection between M1 base finger 4 and orthogonal M2 base finger 12 by via 16.

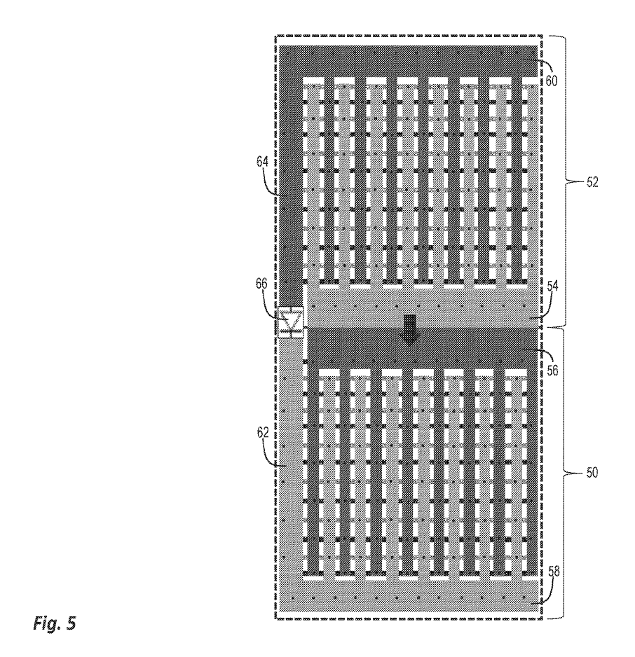

FIG. 5 is a drawing of the backside and second level metallization of a shade management block formed of two electrically connected adjacent solar cells. As previously, although a first level metallization is covered by a supporting backplane and thus non-visible, underlying first level metallization (i.e., under a supporting backplane) is shown in FIG. 5 for descriptive purposes. Solar cell 50 is similar to the solar cell of FIG. 2 and solar cell 52 is similar to solar cell 50 having certain busbar differences. Solar cells 50 and 52 are electrically connected in series through emitter busbar 54 of solar cell 52 and base busbar 56 of solar cell 50—current flows from solar cell 52 to solar cell 50 through the busbar 54 to busbar 56 connection. Emitter busbar 58 is a positive terminal for the solar cell shade management block and base busbar 60 is a negative terminal for the solar cell shade management block. Emitter busbar 58 and base busbar 60 may be electrically connected to additional solar cells or solar cell shade management blocks—for example to build a solar module or solar cell array of electrically connected shade management blocks. In practice, a conductive jumper (or a conductive metal) may be formed to electrically connect busbar 54 and busbar 56, for example a conductive jumper formed as part of the second level metallization or a conductive jumper added to the second level metallization, or busbar 54 and busbar 56 may be formed or patterned to connect such that an electrical series connection is formed between solar cell 50 and solar cell 52. Solar cell 50 and solar cell 52 are also electrically connected by emitter busbar 58 of solar cell 50 and base busbar 60 of solar cell 52 through bypass diode 66. Emitter busbar extension 62 and base busbar extension 64 extend the emitter busbar and base busbar of solar cell 50 and solar cell 52, respectively.

Solar cells 50 and 52 may be supported a single continuous backplane (e.g., a prepreg sheet) over which second level metallization is formed. In other instances, for example when operating under solar cell processing and backplane size requirements, supporting backplanes supporting solar cells to be connected may be stitched, laminated, or otherwise connected together. The supporting backplane provides structural flexibility for the second level metallization for creating shade management blocks of solar cells, portions of solar cells, or combinations thereof

Bypass diode 66 is connected in reverse bias between the positive terminal of solar cell 50 (emitter busbar 58 via emitter busbar extension 62) and the negative terminal of solar cell 52 (base busbar 60 via base busbar extension 64) and in parallel to the base busbar 56 and emitter busbar 54 connection to provide shade management to the shade management block of solar cell 50 and solar cell 52 to shunt electric current around solar cell 50 and solar cell 52 by providing a low resistance current path around solar cell 50 and solar cell 52. Thus, bypass diode 66 prevents overheating of solar cells 50 and 52 in the event of low power production of the shade management block of solar cells 50 or 52 (lower power production as compared to other series connected shade management blocks), for example due to localized shading, by providing a current path around the weak (i.e., lower power producing) shade management block. A feature particularly advantageous in a connection of shade management blocks—such as a series of electrically connected shade management blocks (e.g., with reference to the shade management block of FIG. 5, shade management blocks electrically connected at positive terminals (emitter busbar 58) and negative terminals (base busbar 60)). The bypass diode, and MPPT power optimizer, may be a surface mount device (SMD) using surface mount technology (SMT) attached opposite polarity busbars. The bypass diode, and MDPT power optimizer, may be placed on the backplane or metallized busbars or a combination thereof after formation of the second level metallization. In some instances, it may be advantageous to position a bypass diode to avoid current bends or other bottlenecks.

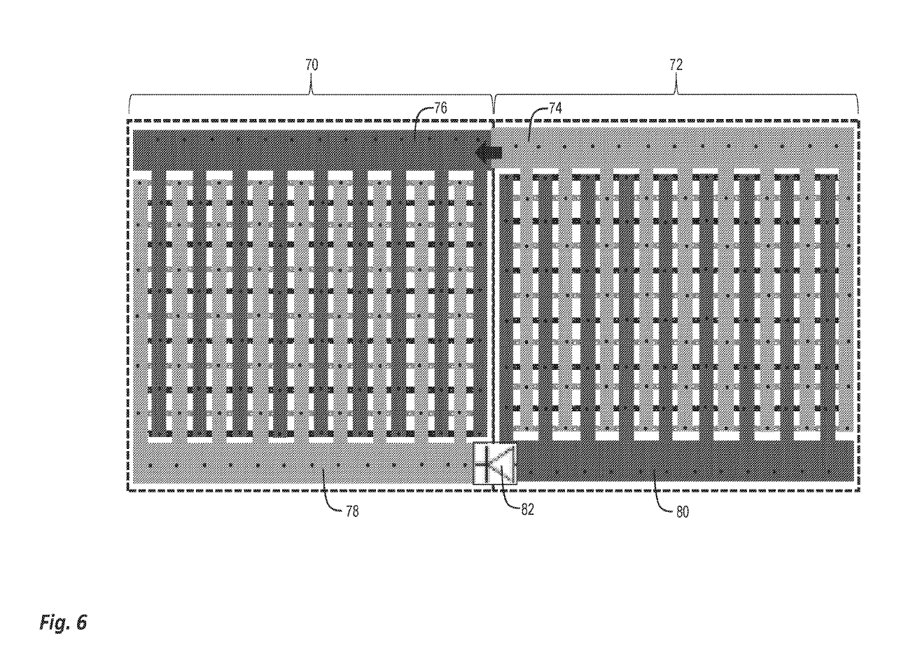

FIG. 6 is a drawing of the backside and second level metallization of a shade management block formed of two electrically connected adjacent solar cells. As previously, although a first level metallization is covered by a supporting backplane and thus non-visible, underlying first level metallization (i.e., under a supporting backplane) is shown in FIG. 5 for descriptive purposes. Solar cell 70 is similar to the solar cell of FIG. 3 and solar cell 72 is similar to solar cell 70 having certain busbar differences. Solar cells 72 and 70 are electrically connected in series through emitter busbar 74 of solar cell 72 and base busbar 76 of solar cell 70—current flows from solar cell 72 to solar cell 70 through the busbar 74 to busbar 76 connection. Emitter busbar 58 is a positive terminal for the solar cell shade management block and base busbar 60 is a negative terminal for the solar cell shade management block. Emitter busbar 58 and base busbar 60 may be electrically connected to additional solar cells or solar cell shade management blocks—for example to build a solar module or solar cell array of electrically connected shade management blocks. In practice, a conductive jumper may be formed to electrically connect busbar 74 and busbar 76, for example a conductive jumper formed as part of the second level metallization or a conductive jumper added to the second level metallization, or busbar 74 and busbar 76 may be formed or patterned to connect such that an electrical series connection is formed between solar cell 72 and solar cell 70. Solar cell 70 and solar cell 72 are also electrically connected by emitter busbar 78 of solar cell 70 and base busbar 80 of solar cell 72 through bypass diode 82.

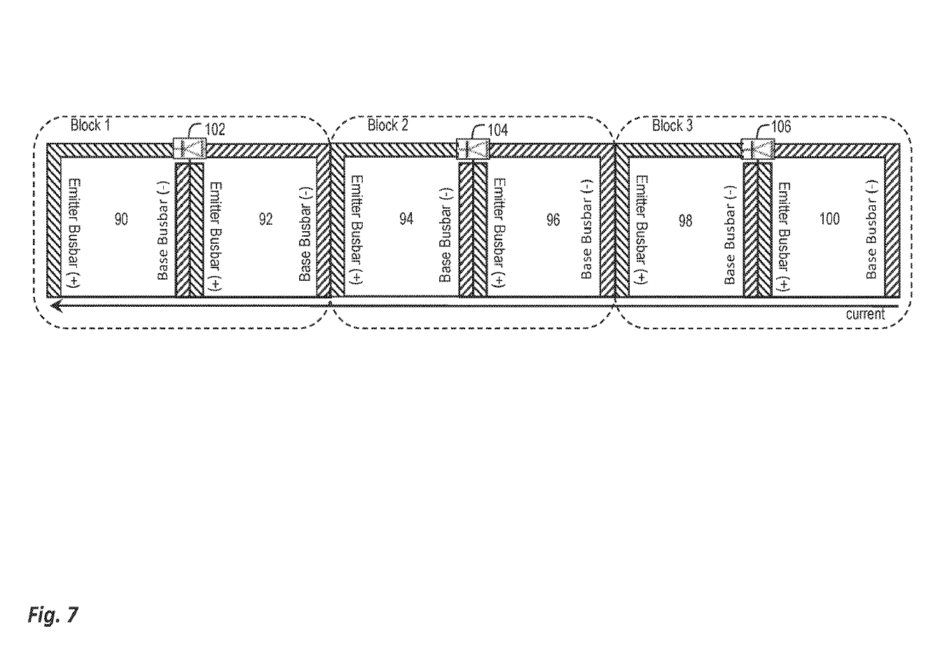

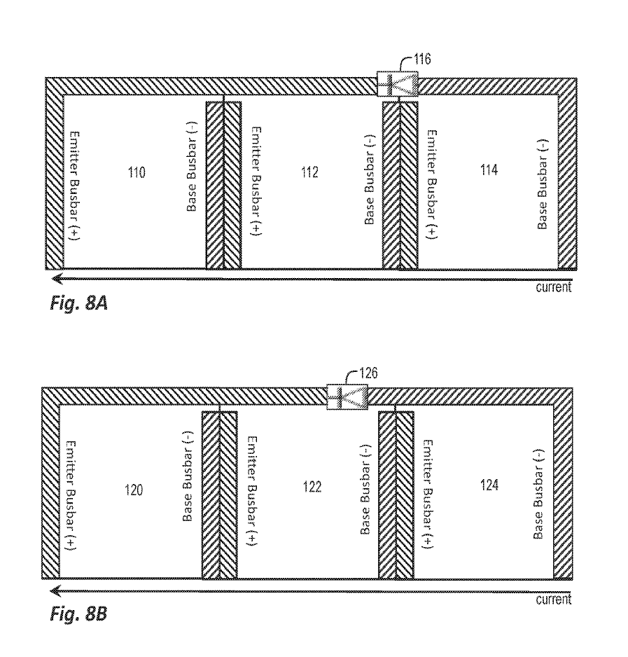

FIGS. 7, 8A, and 8B are drawings of the backside and second level busbar metallization of representative shade management blocks. Note, although not shown in FIGS. 7, 8A, and 8B, the structures of FIGS. 7, 8A, and 8B have interdigitated second level metal base and emitter fingers, such as base fingers 12 and emitter fingers 14 in FIG. 2 and base fingers 32 and emitter fingers 34 in FIG. 3. Additionally, underlying first level metallization (i.e., under a supporting backplane) is not shown.

FIG. 7 is a drawing of the backside and second level busbar metallization of three shade management blocks, Block 1 and Block 2 and Block 3, electrically connected in series. Block 1, Block 2, and Block 3 are made of two solar cells per block. Each shade management block of FIG. 7 (Block 1, Block 2, and Block 3) has a corresponding bypass diode connected in parallel to the cell to cell electrical connection in the shade management block to shunt electric current around the solar cells in the shade management block. Block 1 is made of solar cells 90 and 92, Block 2 is made of solar cells 94 and 96, and Block 3 is made of solar cells 98 and 100.

Block 3 cell to cell current flows from emitter busbar of solar cell 100 to base busbar of solar cell 98. Bypass diode 106 is connected in reverse bias between emitter busbar of solar cell 98 and base busbar of solar cell 100 to provide a low resistant current path for Block 3. Emitter busbar of solar cell 98 of Block 3 is electrically connected to base busbar of solar cell 96 of Block 2 and current flows from Block 3 to Block 2. Block 2 cell to cell current flows from emitter busbar of solar cell 96 to base busbar of solar cell 94. Bypass diode 104 is connected in reverse bias between emitter busbar of solar cell 94 and base busbar of solar cell 96 to provide a low resistant current path for Block 2. Emitter busbar of solar cell 94 of Block 2 is electrically connected to base busbar of solar cell 92 of Block 1 current flows from Block 2 to Block 1. Block 1 cell to cell current flows from emitter busbar of solar cell 92 to base busbar of solar cell 90. Bypass diode 102 is connected in reverse bias between emitter busbar of solar cell 90 and base busbar of solar cell 92 to provide a low resistant current path for Block 1.

In the event of a low power producing solar cell (for example due to localized shading of the cell and a portion of the cell), and thus lower power producing shade management block as compared to other electrically connected shade management blocks, the bypass diode corresponding to the lower producing shade management block provides a low resistance (and relatively loss loss) electrical current path to bypass the solar cells in the lower producing shade management block and thus avoid the low power producing solar cells from overheating.

FIG. 8A is a drawing of the backside and second level busbar metallization of a shade management blocks made of three solar cells. Solar cell 110, solar cell 112, and solar cell 114 are connected in electrical series and form one shade management block.

Bypass diode 116 is electrically connected in parallel to the series connection of the shade management block of FIG. 8A and in reverse bias between the positive to negative output of the shade management block.

FIG. 8B is a drawing of the backside and second level busbar metallization of a shade management blocks made of three solar cells similar to the shade management block of FIG. 8A and with an offset bypass diode. Solar cell 120, solar cell 122, and solar cell 124 are connected in series and form one shade management block. Bypass diode 126 is electrically connected in parallel to the series connection of the shade management block of FIG. 8B and in reverse bias between the positive to negative output of the shade management block. Bypass diode 126 terminal connections are electrically offset from the cell to cell series connection of solar cell 122 and solar cell 124 (and similarly offset from the cell to cell series connection of solar cell 120 and solar cell 122).

The integrated solar cell metallization and solar cell electronics forming shade management blocks of solar cells or solar cell regions provide for flexible shade management block design. Advantageously, flexible shade management block design may be used to form shade management blocks of varying current and voltage characteristics made of solar cells or solar cell regions of varying current and voltage characteristics. In operation, solar cell electronics (e.g., a bypass diode) may be constrained by current and voltage characteristics such that the size or cost (or both cost and size) of a solar cell electronic increases with the current or voltage requirements (current particularly) of the solar cell electronic. Additionally first level metallization, second level metallization, and conductive vias connecting first level metallization and second level metallization may be benefit from reduced current and metallization conductance and thickness requirements as reduced metallization conductance reduces strain on relatively fragile semiconductor material (e.g., silicon) thus increasing reliability and reducing potential solar cell failures and manufacturing capability as well as reducing metallization cost.

In some instances, the voltage may be scaled up and the current scaled down to enable use of much smaller/less expensive electronic components (allowing for lamination improvement and reducing component package and module thickness, as well as improved module reliability and reduced overall module cost) and reduce dissipation losses associated with bulkier components. Locally at the cell level, reducing component size may reduce dissipation losses (in some instances resulting in a fraction of the dissipation losses).

A solar cell having isled sub-cells or regions and referred to herein as a monolithically isled solar cell or iCell may be used to increase (scale-up) voltage and decrease (scale-down) current to enable low-cost, low-loss solar cell electronics and improved module performance. Detail relating to monolithically isled solar cells and two level metallization and backplane structures discussed herein may be found in U.S. Patent Pub. 2014/0370650 published Dec. 18, 2014 which is hereby incorporated by reference in its entirety. Relating to monolithically isled solar cells, a shade management block may be defined as a building block unit comprising from a fraction (less than one) to one monolithic isled solar cell to more than a single (greater than one) monolithic isled solar cell within its structure. For example, a shade management block may comprise a fraction F (up to 100%) of M monolithic isled solar cells, wherein M may be either an integer or a fractional number (e.g., M=3/2, 2, 5/2, 3, etc.)

Physically or regionally isolated isles or regions (i.e., the initial semiconductor layer or substrate, for example a 156×156 mm or a 210×210 mm wafer, partitioned into a plurality of substrate isles supported on a shared continuous backplane) are formed from an initially continuous semiconductor layer or substrate (e.g., a ˜156×156 mm or a ˜210×210 mm wafer)—thus the resulting isles (for instance, trench isolated from one another using trench isolation regions or cuts through the semiconductor substrate) are monolithic and are attached to and supported by a continuous electrically insulating backplane (for example a flexible backplane such as an electrically insulating prepreg layer). The completed solar cell (referred to as a master cell or iCell) comprises a plurality of monolithically integrated isles/sub-cells/mini-cells/regions, in some instances attached to a backplane (e.g., for example a backplane having a relatively good Coefficient of Thermal Expansion or CTE match to that of the semiconductor substrate material such as crystalline silicon such as a backplane made of a prepreg materials) providing increased solar cell flexibility and pliability while suppressing or even eliminating micro-crack generation and crack propagation or breakage in the semiconductor substrate layer. The electrically insulating backplane may be a flexible electrically insulating backplane further enhances solar cell flexibility. Further, a monolithically isled (or monolithically integrated group of isles) solar cell (iCell) provides improved cell planarity and relatively small or negligible cell bow throughout solar cell processing steps such as any optional semiconductor layer thinning etch, texture etch, post-texture clean, PECVD passivation and anti-reflection coating (ARC) processes (and in some processing embodiments also allow for sunny-side-up PECVD processing of the substrates due to mitigation or elimination of thermally-induced cell warpage), and second level solar cell metallization.

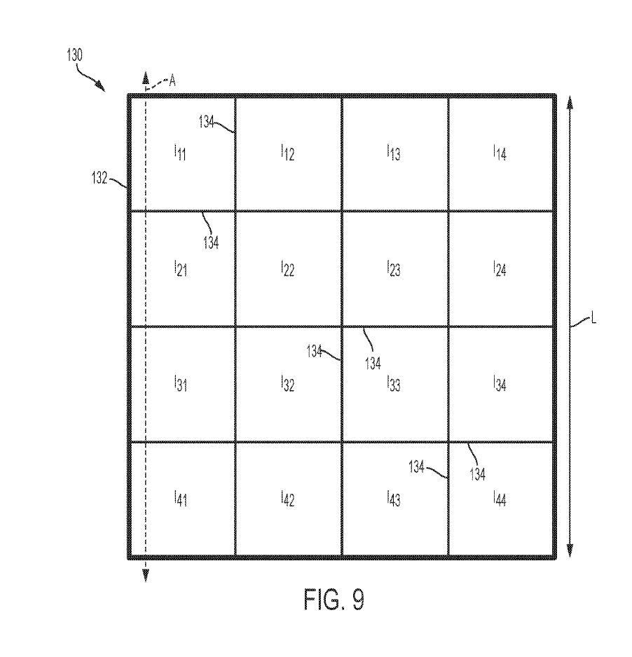

FIG. 9 is a representative schematic plan view (frontside or sunnyside view) diagram of an icell (or monolithically isled cell) pattern (shown for square-shaped isles and square-shaped iCell) along with uniform-size (equal-size) square-shaped isles for N×N=4×4=16 isles (or sub-cells, mini-cells, tiles). This schematic diagram shows a plurality of isles (shown as 4×4=16 isles) partitioned by trench isolation regions. The number of isles (or regions) N in an iCell (or monolithically isled cell) scales the iCell voltage up by N and the iCell current down by N. In other words, an iCell (or monolithically isled cell) with 12 isles has a voltage 12 times (12×) and a current 1/12 times ( 1/12×) of a non-isled or non-partitioned cell having the same dimensions of the icell.

FIG. 9 is a schematic diagram of a top or plan view of a 4×4 uniform isled (tiled) master solar cell or monolithically isled solar cell or iCell 130 defined by cell peripheral boundary or edge region 132, having a side length L, and comprising sixteen (16) uniform square-shaped isles formed from the same original continuous substrate and identified as I₁₁ through I₄₄ attached to a continuous backplane on the master cell backside (backplane and solar cell backside not shown). Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and in some instances less than or equal to approximately 100 μm—for instance, in the range of a few up to approximately 100 μm) shown as trench isolation or isle partitioning borders 134. Main cell (or iCell) peripheral boundary or edge region 132 has a total peripheral length of 4 L; however, the total iCell edge boundary length comprising the peripheral dimensions of all the isles comprises cell peripheral boundary 132 (also referred to as cell outer periphery) and trench isolation borders 134. Thus, for an iCell comprising N×N isles or mini-cells in a square-shaped isle embodiment, the total iCell edge length is N×cell outer periphery. In the representative example of FIG. 9 showing an iCell with 4×4=16 isles, N=4, so total cell edge length is 4×cell outer periphery 4L=16 L (hence, this icell has a peripheral dimension which is 4 times larger than that of a standard square shaped cell). For a square-shaped master cell or iCell with dimensions 156 mm×156 mm, square isle side dimensions are approximately 39 mm×39 mm and each isle or sub-cell has an area of 15.21 cm² per isle.

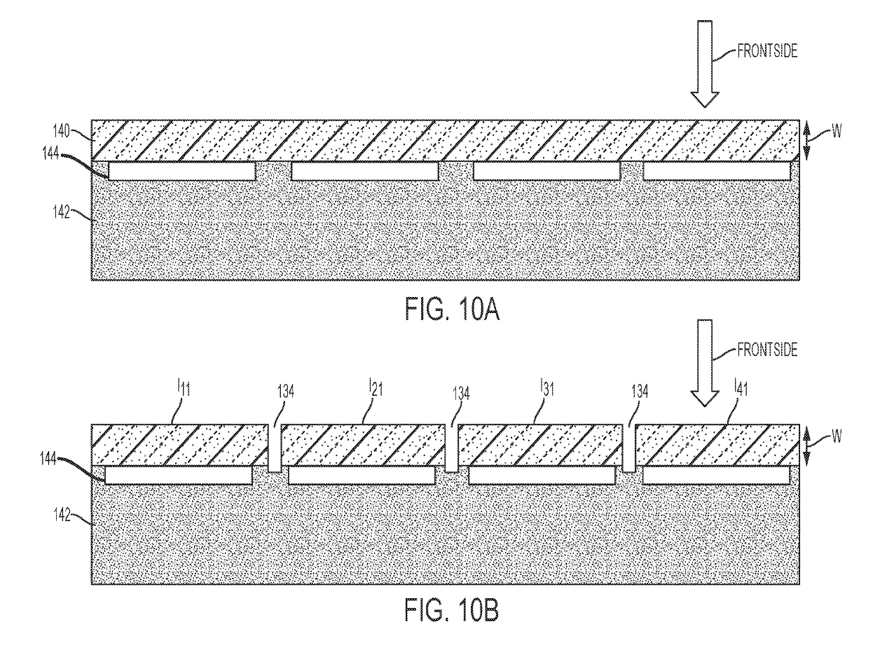

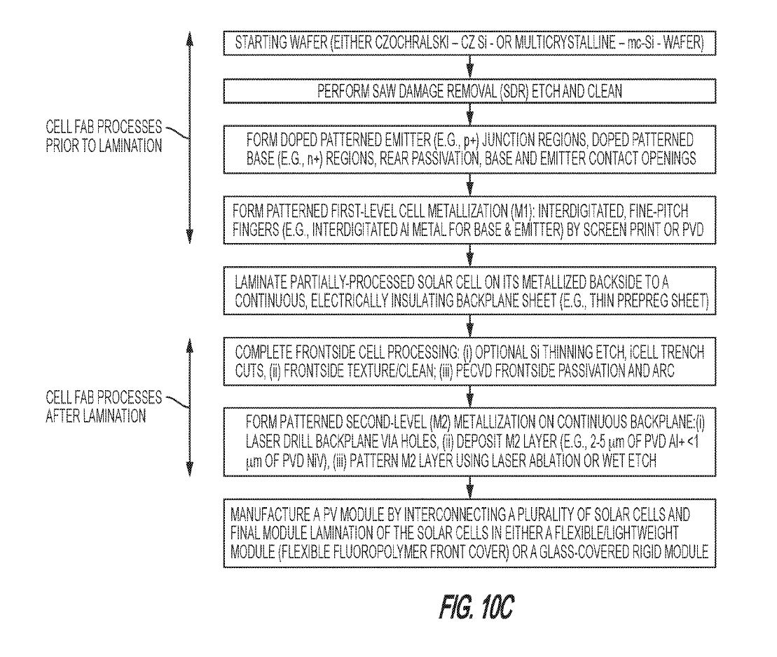

FIGS. 10A and 10B are representative schematic cross-sectional view diagrams of a backplane-attached solar cell during different stages of solar cell processing. FIG. 10A shows the simplified cross-sectional view of the backplane-attached solar cell after processing steps and before formation of the partitioning trench regions. FIG. 10B shows the simplified cross-sectional view of the backplane-attached solar cell after some processing steps and after formation of the partitioning trench regions to define the trench-partitioned isles. FIG. 10B shows the schematic cross-sectional view of the monolithic isled solar cell or iCell of FIG. 9 along the view axis A of FIG. 9 for an monolithic isles solar cell or iCell pattern (shown for square-shaped isles and square-shaped iCell), indicating the uniform-size (equal-size) square-shaped isles for N×N=4×4=16 isles (or sub-cells, mini-cells, tiles).

FIGS. 10A and 10B are schematic cross-sectional diagrams of a monolithic master cell semiconductor substrate on a backplane before formation of trench isolation or partitioning regions, and a monolithic isled or tiled solar cell on a backplane formed from a master cell after formation of trench isolation or partitioning regions, respectively. FIG. 10A comprises semiconductor substrate 140 having width (semiconductor layer thickness) W and first level metallization 144 (first level metallization having base and emitter metallization) and attached to backplane 142 (e.g., an electrically insulating continuous backplane layer, for instance, a thin flexible sheet of prepreg). FIG. 10B is a cross-sectional diagram of an isled solar cell (iCell)—shown as a cross-sectional diagram along the A axis of the cell of FIG. 9. Shown, FIG. 10B comprises isles or mini-cells I₁₁, I₂₁, I₃₁, and I₄₁ each having a trench-partitioned semiconductor layer width (thickness) W and attached to backplane 142. The semiconductor substrate regions of the mini-cells are physically and electrically isolated by an internal peripheral partitioning boundary, trench partitioning borders 134. The semiconductor regions of isles or mini-cells or sub-cells I₁₁, I₂₁, I₃₁, and I₄₁ are monolithically formed from the same continuous semiconductor substrate shown in FIG. 10A. The monolithic isled solar cell or iCell of FIG. 10B may be formed from the semiconductor/backplane structure of FIG. 10A by forming internal peripheral partitioning boundaries in the desired mini-cell shapes (e.g., square shaped mini-cells or isles) by trenching through the semiconductor layer to the attached backplane (with the trench-partitioned isles or mini-cells being supported by the continuous backplane). Trench partitioning of the semiconductor substrate to form the isles does not partition the continuous backplane sheet, hence the resulting isles remain supported by and attached to the continuous backplane layer or sheet. Trench partitioning formation process through the initially continuous semiconductor substrate thickness may be performed by, for example, pulsed laser ablation or dicing, mechanical saw dicing, ultrasonic dicing, plasma dicing, water jet dicing, or another suitable process (dicing, cutting, scribing, and trenching may be used interchangeably to refer to the process of trench isolation process to form the plurality of isles or mini-cells or tiles on the continuous backplane). The backplane structure of the solar cell may comprise a combination of a backplane support in conjunction with an integrated metallization structure, with the backplane support providing mechanical support to the semiconductor layer and structural integrity for the resulting iCell (e.g., a flexible or bendable solar cell using a flexible backplane sheet or a rigid solar cell using a rigid backplane sheet or a semi-flexible solar cell using a semi-flexible backplane sheet). The term backplane refers to the supporting backplane (for instance, an electrically insulating thin sheet of prepreg) which is attached to the semiconductor substrate backside and supports the icell semiconductor substrate regions and supports the solar cell two level metallization structure.

FIG. 10C is a high level solar cell and module fabrication process flow embodiment using starting crystalline (mono-crystalline or multi-crystalline) silicon wafers. FIG. 10C shows a high-level iCell process flow for fabrication of backplane-attached back-contact/back-junction (IBC) iCells using two layers of metallization: M1 and M2. The first layer or level of patterned cell metallization M1 is formed as essentially the last process step among a plurality of front-end cell fab processes prior to the backplane lamination to the partially processed iCell (or a larger continuous backplane attached to a plurality of partially processed iCells when fabricating monolithic modules as described earlier). The front-end cell fab processes outlined in the top 4 boxes of FIG. 10C essentially complete the back-contact/back-junction solar cell backside structure through the patterned M1 layer. Patterned M1 is designed to conform to the iCell isles (sub-cells or mini-cells) and comprises a fine-pitch interdigitated metallization pattern. In FIG. 10C, the fifth box from the top involves attachment or lamination of the backplane layer or sheet to the partially processed icell backside (or to the backsides of a plurality of partially processed iCells when making a monolithic module). In FIG. 10C, the sixth and seventh boxes from the top outline the back-end or post-backplane-attachment (also called post-lamination) cell fab processes to complete the remaining frontside (optional silicon wafer thinning etch to form thinner silicon absorber layer if desired, partitioning trenches, texturization, post-texturization cleaning, passivation and ARC) as well as the via holes and second level or layer of patterned metallization M2. Example “post-lamination” processes (or the back-end cell fab processes performed after the backplane attachment) are outlined in the sixth and seventh boxes of FIG. 10C. The bottom box in FIG. 10C describes the final assembly of the resulting iCells into either flexible, lightweight PV modules or into rigid glass-covered PV modules. If the process flow results in a monolithic module comprising a plurality of iCells monolithically interconnected together by the patterned M2 (as described earlier for the epitaxial silicon lift off process flow), the remaining PV module fabrication process outlined in the bottom box of FIG. 10C would be simplified since the plurality of the interconnected iCells sharing a larger continuous backplane and the patterned M2 metallization for cell-to-cell interconnections are already electrically interconnected and there is no need for tabbing and/or stringing and/or soldering of the solar cells to one another. The resulting monolithic module can be laminated into either a flexible, lightweight PV module (for instance, using a thin flexible fluoropolymer cover sheet such as ETFE or PFE on the frontside instead of rigid/heavy glass cover sheet) or a rigid, glass-covered PV module.

The design of isles or mini-cells (sub-cells) of an iCell may include various geometrical shapes such as squares, triangles, rectangles, trapezoids, polygons, honeycomb hexagonal isles, or many other possible shapes and sizes. The shapes and sizes of isles, as well as the number of isles in an iCell may be selected to provide optimal attributes for one or a combination of the following considerations: (i) overall crack elimination or mitigation in the master cell (iCell); (ii) enhanced pliability and flexibility/bendability of master cell (iCell) without crack generation and/or propagation and without loss of solar cell or module performance (power conversion efficiency); (iii) reduced metallization thickness and conductivity requirements (and hence, reduced metallization material consumption and processing cost) by reducing the master cell (iCell) current and increasing the iCell voltage (through series connection or a hybrid parallel-series connection of the isles in the monolithic iCell, resulting in scaling up the voltage and scaling down the current); and (iv) providing relatively optimum combination of electrical voltage and current ranges in the resulting icell to facilitate and enable implementation of inexpensive distributed embedded electronics components on the iCells and/or within the laminated PV modules comprising iCells.

Partitioning the main/master cell into an array of isles or sub-cells (such as an array of N×N square or pseudo-square shaped or K triangular-shaped or a combination thereof) and interconnecting those isles in electrical series or a hybrid combination of electrical parallel and electrical series reduces the overall master cell current for each isle or mini-cell—for example by a factor of N×N=N² if all the square-shaped isles are connected in electrical series, or by a factor of K if all the triangular-shaped isles are connected in series. And while the main/master cell or iCell has a maximum-power (mp) current of Iₘₚ, and a maximum-power voltage of Vₘₚ, each series-connected isle (or sub-groups of isles connected in parallel and then in series) will have a maximum-power current of Iₘₚ/N² (assuming N² isles connected in series) and a maximum-power voltage of Vₘₚ (no change in voltage for the isle). Designing the first and second metallization layer patterns, M1 and M2 respectively, such that the isles on a shared continuous or continuous backplane are connected in electrical series results in a main/master cell or icell with a maximum-power current of Iₘₚ/N² and a maximum power voltage of N²×Vₘₚ or a cell (icell) maximum power of Pₘₚ=Iₘₚ×Vₘₚ (the same maximum power as a master cell without mini-cell partitioning).

Thus, a monolithically isled master cell or iCell architecture reduces ohmic losses due to reduced solar cell current and allows for thinner solar cell metallization structure generally and a much thinner M2 layer if applicable or desired. Further, reduced current and increased voltage of the master cell or iCell allows for relatively inexpensive, high-efficiency, maximum-power-point-tracking (MPPT) power optimizer electronics to be directly embedded into the PV module and/or integrated on the solar cell backplane.

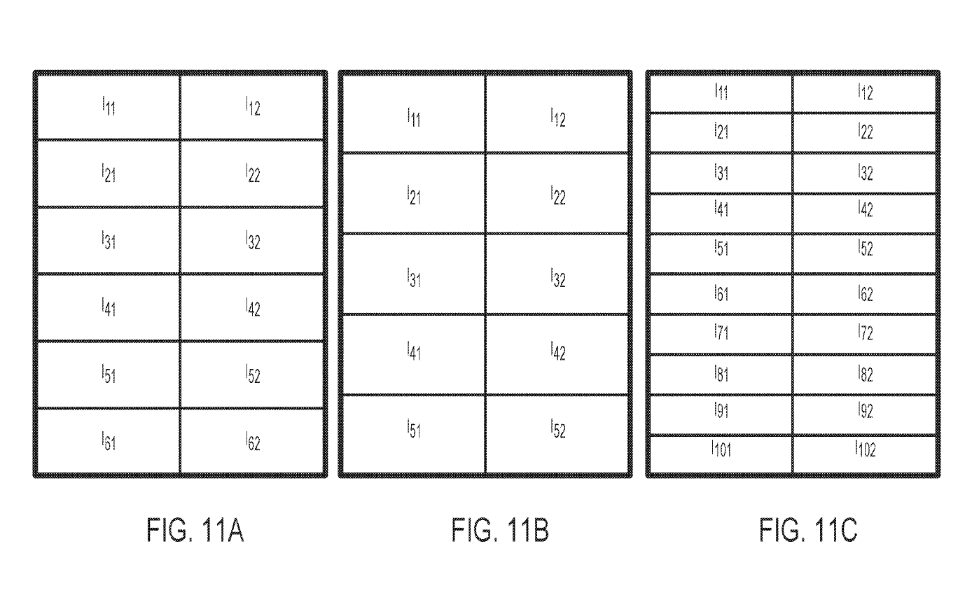

FIGS. 11A, 11B, and 11C are drawings of backplane-attached solar cell (iCell) embodiments showing arrays of uniform rectangular shaped mini-cells or sub-cells (i.e., isles or mini-cells all having essentially the same areas). FIG. 11A is a representative schematic plan view (frontside or sunnyside view) diagram of an iCell pattern (shown for rectangular-shaped isles and square-shaped iCell) along with uniform-size (equal-size) rectangular-shaped isles for N×M=2×6=12 isles (or sub-cells, mini-cells, tiles). This schematic diagram shows a plurality of isles I₁₁ through I₆₂ (shown as 2×6=12 isles) partitioned by trench isolation regions. FIG. 11B is a representative schematic plan view (frontside or sunnyside view) diagram of an iCell pattern (shown for rectangular-shaped isles and square-shaped iCell) along with uniform-size (equal-size) rectangular-shaped isles for N×M=2×5=10 isles (or sub-cells, mini-cells, tiles). This schematic diagram shows a plurality of isles I₁₁ through I₅₂ (shown as 2×5=10 isles) partitioned by trench isolation regions. FIG. 11C is a representative schematic plan view (frontside or sunnyside view) diagram of an iCell pattern (shown for rectangular-shaped isles and square-shaped iCell) along with uniform-size (equal-size) rectangular-shaped isles for N×M=2×10=20 isles (or sub-cells, mini-cells, tiles). This schematic diagram shows a plurality of isles I₁₁ through I₁₀₂ (shown as 2×10=20 isles) partitioned by trench isolation regions.

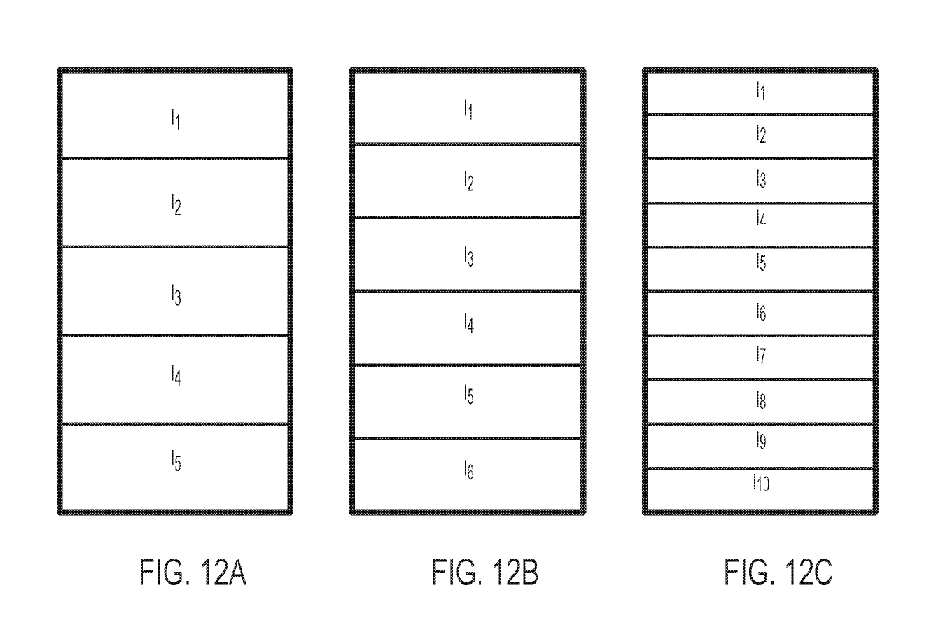

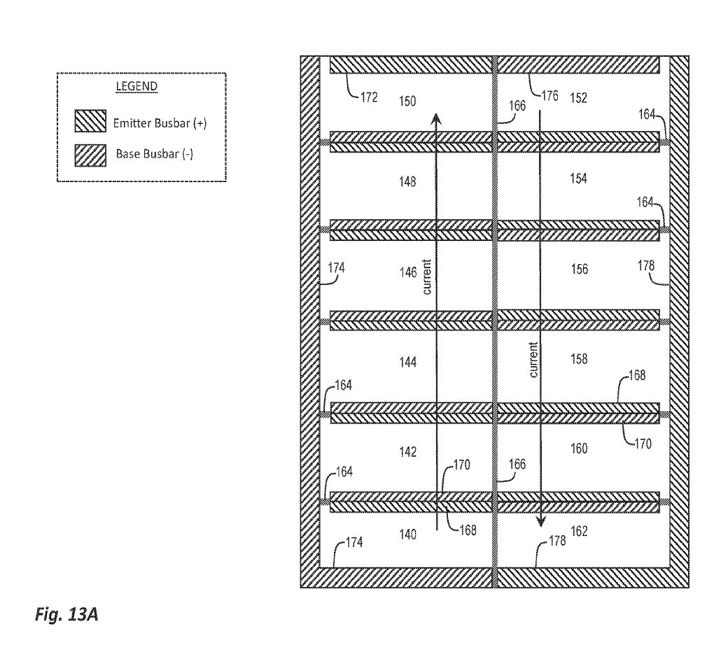

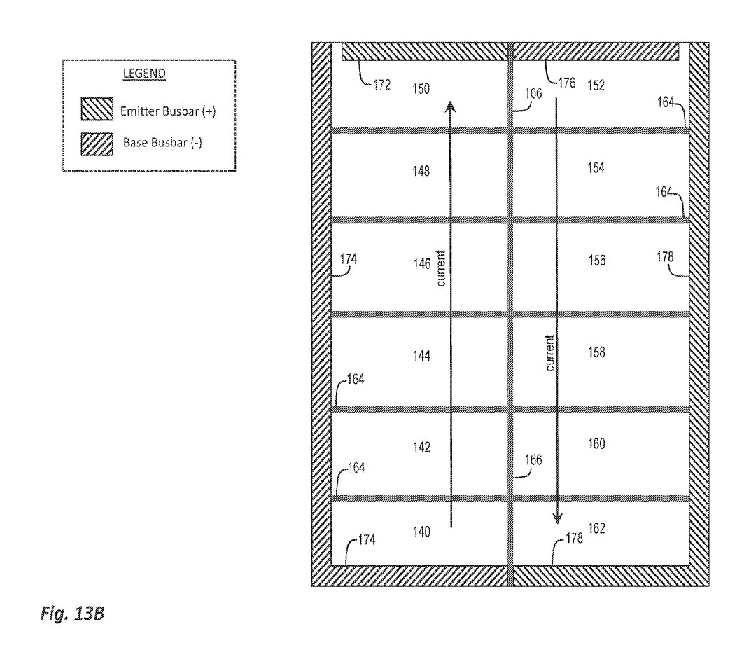

FIGS. 12A, 12B, and 12C are drawings of backplane-attached solar cell (iCell) embodiments showing arrays of uniform rectangular-shaped mini-cells (i.e., isles or mini-cells all having essentially the same areas) similar to cells of FIGS. 11A, 11B, and 11C and without trench isolation region such as the trench isolation region between isles I₁₁ and I₁₂ in FIG. 11A. Trench isolation regions (e.g., scribes) may also be mechanical only (i.e., for flexibility and not corresponding to second level metallization).

FIG. 12A is a representative schematic plan view (frontside or sunnyside view) diagram of an iCell pattern (shown for rectangular-shaped isles and iCell) along with uniform-size (equal-size) rectangular-shaped isles for N×M=1×5=5 isles (or sub-cells, mini-cells, tiles). This schematic diagram shows a plurality of isles Ii through 15 (shown as 1×5=10 isles) partitioned by trench isolation regions. FIG. 12B is a representative schematic plan view (frontside or sunnyside view) diagram of an iCell pattern (shown for rectangular-shaped isles and iCell) along with uniform-size (equal-size) rectangular-shaped isles for N×M=1×6=6 isles (or sub-cells, mini-cells, tiles). This schematic diagram shows a plurality of isles I₁ through I₆ (shown as 1×6=6 isles) partitioned by trench isolation regions. FIG. 12C is a representative schematic plan view (frontside or sunnyside view) diagram of an iCell pattern (shown for rectangular-shaped isles and iCell) along with uniform-size (equal-size) rectangular-shaped isles for N×M=1×10=10 isles (or sub-cells, mini-cells, tiles). This schematic diagram shows a plurality of isles I₁ through I₁₀ (shown as 1×10=10 isles) partitioned by trench isolation regions.

Each isle (or region) of a monolithically isled solar cell may have a first level metallization such as that shown in FIG. 1 and a second level metallization such as that shown in FIGS. 2 and 3. Isles within a monolithically isled solar cell may be electrically connected in series, parallel, or a combination of series and parallel through second level metallization busbars of each isle.

Note the drawings following, trench isolation regions are shown for functional understanding of the solar cell isles or regions, however, viewed from the backside the trench isolation regions would be non-visible as they are covered by the supporting backplane.

FIGS. 13A and 13B are drawings of the backside and second level busbar metallization of a 2×6 monolithically isled solar cell having 12 isles (or regions or sub-cells). As shown in FIG. 13A, solar cell isles (or regions) 140, 142, 144, 146, 148, 150, 152, 154, 156, 158, 160, and 162 form a monolithically isled solar cell and are defined by x-axis trench isolation regions 164 and y-axis trench isolation region 166. Isle (or region) second metallization busbars 168 (emitter) and 170 (base) electrically connect isles through opposite polarity busbar connection (interdigitated second level base and emitter metallization fingers corresponding to emitter busbars 168 and base busbars 170 not shown). Isles 140, 142, 144, 146, 148, and 150 (a monolithically isled half plane of isles divided by y-axis trench isolation region 166) are connected in series and isles 152, 154, 156, 158, 160, and 162 are connected in series (a monolithically isled half plane of isles divided by y-axis trench isolation region 166). Base busbar 174 (L-shaped base busbar) and emitter busbar 172 provide electrical connection for the half plane of isles 140, 142, 144, 146, 148, and 150 and base busbar 176 and emitter busbar 178 (L-shaped emitter busbar) provide electrical connection for the half plane of isles 152, 154, 156, 158, 160, and 162. Here, emitter and base busbars are provided on all four sides of the monolithically isled solar cell. Additionally, for example, base busbar 174 and emitter busbar 178 (and particularly peripheral or runner portions of base busbar 174 and emitter busbar 178, for example the peripheral or runner portions traversing isles 140, 142, 144, 146, 148, and 150) may have a width of approximately 3 mm or greater. In some instances, it may advantageous to attach the bypass diode at the cells peripheral margins—for example mounted on the supporting backplane. A solar cell power optimizer such as an MDPT power optimizer (e.g., a 2.5 A 10V power optimizer) may be combined with the bypass diode.

For shade management block descriptive clarity, FIG. 13B is a drawing of the 2×6 monolithically isled solar cell of FIG. 13A without showing the isle to isle (or region to region) busbar connection.

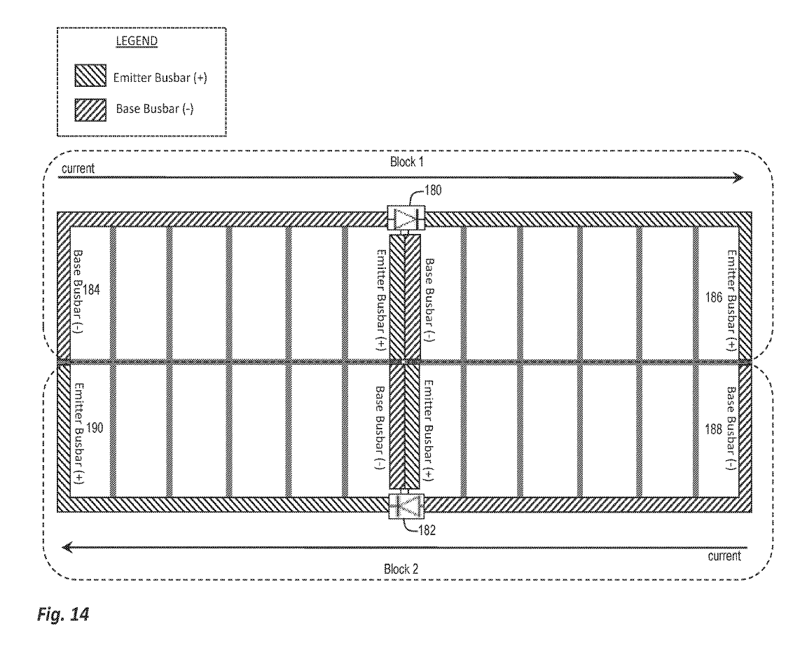

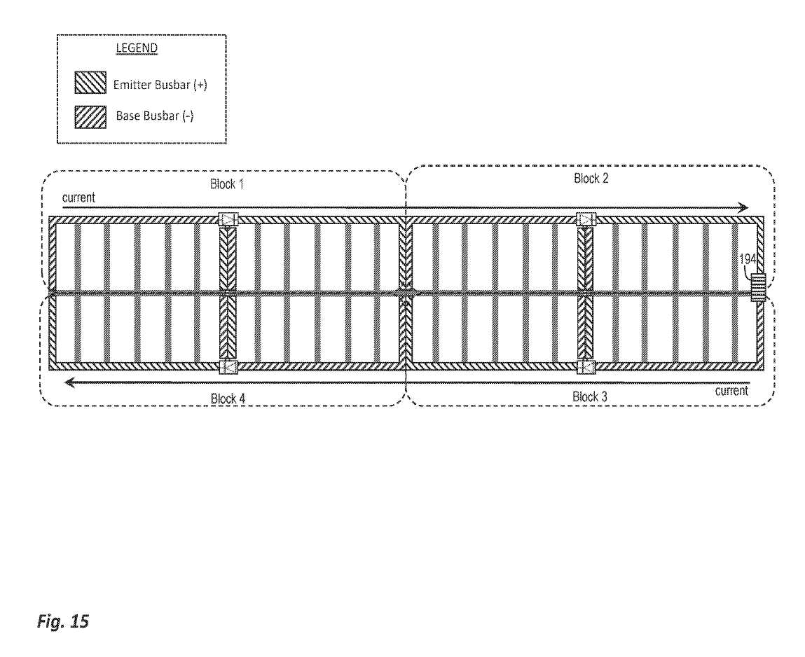

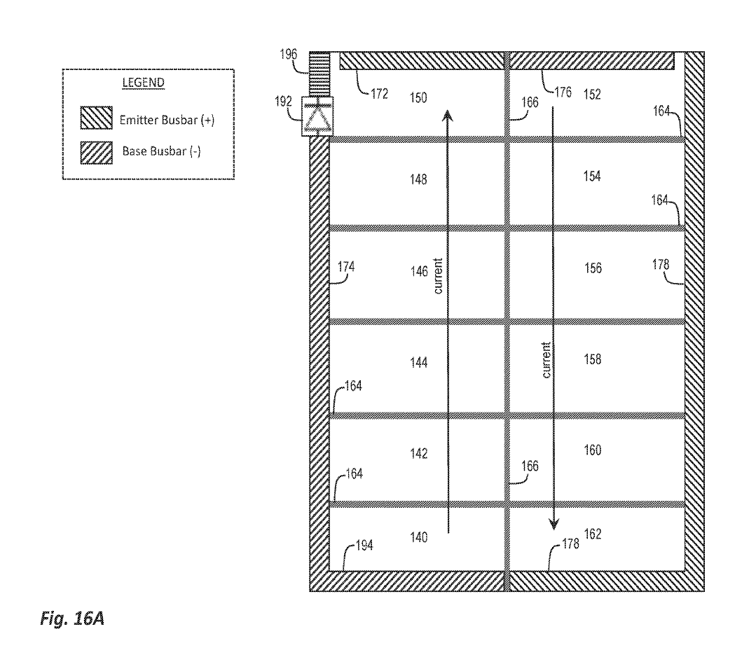

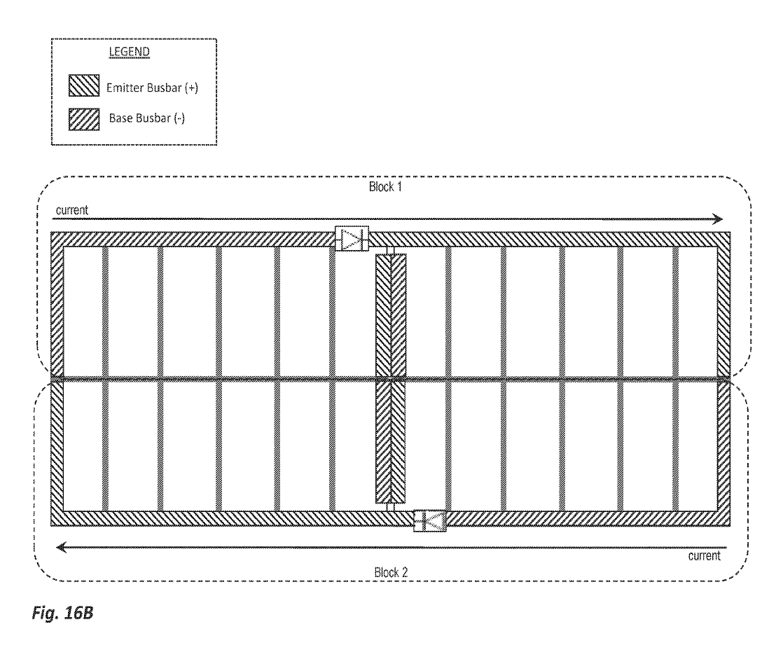

FIGS. 14 and 15 are drawings of the backside and second level busbar metallization of shade management blocks made of two electrically connected monolithically isled half planes. Note, although not shown, each isle has interdigitated second level metal base and emitter fingers and corresponding a base and emitter busbar. Additionally, underlying first level metallization (i.e., under a supporting backplane) is not shown.

FIG. 14 is a drawing of the backside and second level busbar metallization of two shade management blocks, Block 1 and Block 2. Both Block 1 and Block 2 are each made of two electrically connected monolithically isled half planes (e.g., the monolithically isled half plane of FIGS. 13A and 13B made of series connected solar cell isles 140, 142, 144, 146, 148, and 150). Each shade management block (Block 1 and Block 2) has a corresponding bypass diode connected in parallel to the isle to isle electrical connection in the shade management block to shunt electric current around the solar isles in the shade management block. Block 1 isle to isle current flows from solar isle 184 to solar isle 186 via second level metallization isle to isle busbar connection. Bypass diode 180 is connected in parallel to current flow and in reverse bias between emitter busbar of isle 186 and base busbar of isle 184 to provide a low resistant current path for Block 1. Block 2 isle to isle current flows from solar isle 188 to solar isle 190 via second level metallization isle to isle busbar connection. Bypass diode 182 is connected in parallel to current flow in reverse bias between emitter busbar of isle 190 and base busbar of isle 188 to provide a low resistant current path for Block 2.

FIG. 15 is a drawing of the backside and second level busbar metallization of four shade management blocks consistent with those shown in FIGS. 13A, 13B, and 14. Electrical current flows from Block 1 to Block 2 to Block 3 to Block 4. Block 2 is connected to Block 3 by connector 194. In the event of a low power producing solar isle (for example due to localized shading), and thus lower power producing shade management block as compared to other electrically connected shade management blocks, the bypass diode corresponding to the lower producing shade management block provides a low resistance current path to bypass the solar isles in the lower producing shade management block and thus avoid the low power producing solar isles from overheating.

Relating to power dissipation of the bypass diode (with reference to a Schottky Barrier Rectifier SBR) and bypass diode connection (with reference to second level metallization M2) in shade management mode (e.g., during shading or a low power producing isle): assume L is the monolithically isled solar cell side dimension (for example along isles 140, 142, 144, 146, 148, and 150 in FIG. 13A), W is the busbar width, T is the M2 thickness, ρ is the M2 metal resistivity, and Iₘₚ is the maximum-power STC (standard test conditions) module current; assume P_{M2} and P_{SBR} are the power loss components of the M2 interconnection and the SBR, respectively, when a shade management building block is shaded and its SBR is turned on; solving the integral equation P_{M2}=2.[(ρ.L)/(6.W.T)].Iₘₚ²+2.[(ρ.L)/(W.T)].Iₘₚ², then P_{M2}=(ρ.L)/(W.T)](2+⅓).Iₘₚ², thus PM2=(7.ρ.L)/(3.W.T)].Iₘₚ². Now, assuming W=3.5 mm (3 mm directly over cell busbar plus 0.5 mm in spacing between cells M2 busbar width), T=3 μm of copper with ρ≈2.18 μΩ.cm (30% higher than bulk copper resistivity of 1.68 μΩ.cm), equivalent to ˜5 μm of aluminum with resistivity of 3.67 μΩ.cm (30% higher than bulk aluminum resistivity of 2.82 μΩ.cm), L=15.6 cm, Iₘₚ=0.757 A: P_{M2}=(7×2.18×10⁻⁶ Ω.cm x 15.6 cm)/(3×0.35 cm×3×10⁻⁴ cm)].(0.757 A)², thus P_{M2}=0.43 W. So: P_{SBR}=V_{F}—Iₘₚ≈0.4 V×0.757 A=0.30 W; P_{shade}=P_{M2}+P_{SBR}=0.43 W+0.30 W, then P_{shade}=0.73 W@STC Iₘₚ; and, P_{shade}/Pₘₚ=0.73/5.54≈0.13 or 13% of STC Pₘₚ under STC condition.

FIGS. 16A is a drawing of the backside and second level busbar metallization of a 2×6 monolithically isled solar cell consistent with the 2×6 monolithically isled solar cell of FIG. 13B and designed for an offset bypass diode such that the bypass diode does not cover the stitching interface between series connected solar isles or solar cells. In some instances, it may advantageous to avoid a bypass diode over a stitching interface. Bypass diode 192 is attached to base busbar 194 and metallization 196. Metallization 196 is structured for connection to a charged busbar. FIG. 16B is a drawing showing the 2×6 monolithically isled solar cell of FIG. 16A forming two shade management blocks, Block 1 and Block 2, each made of a two monolithically isled half planes similar to FIG. 14 which shows the 2×6 monolithically isled solar cell of FIG. 13B forming two shade management blocks.

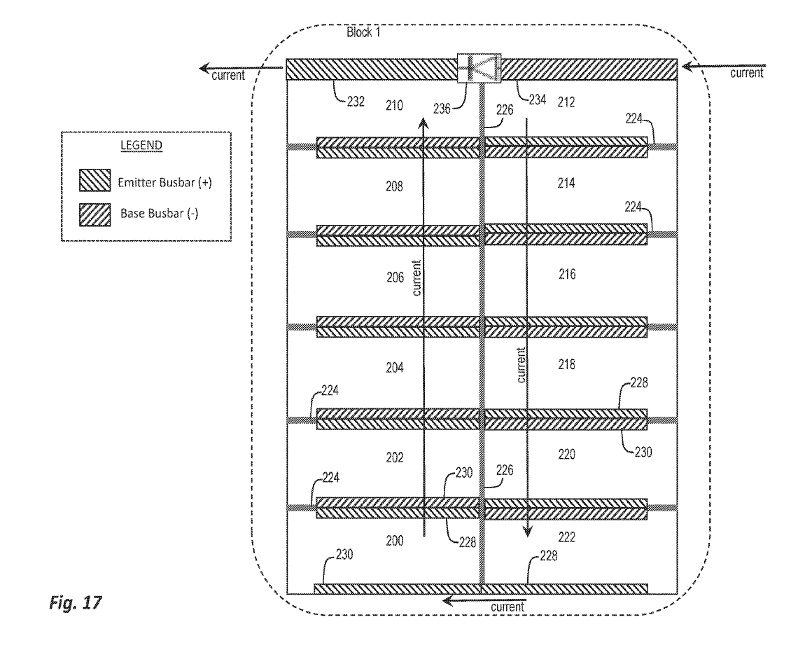

FIG. 17 is a drawing of the backside and second level busbar metallization of a 2×6 monolithically isled solar cell forming a shade management block, Block 1. As shown in FIG. 17, solar cell isles (or regions) 200, 202, 204, 206, 208, 210, 212, 214, 216, 218, 220, and 222 form a monolithically isled solar cell and are defined by x-axis trench isolation regions 224 and y-axis trench isolation region 226. Isle (or region) second metallization busbars 228 (emitter) and 230 (base) electrically connect isles through opposite polarity busbar connection (interdigitated second level base and emitter metallization fingers corresponding to emitter busbars 228 and base busbars 230 not shown). Bypass diode 236 is connected in parallel to current flow and in reverse bias between emitter busbar 232 and base busbar 234 to provide a low resistant current path for Block 1.

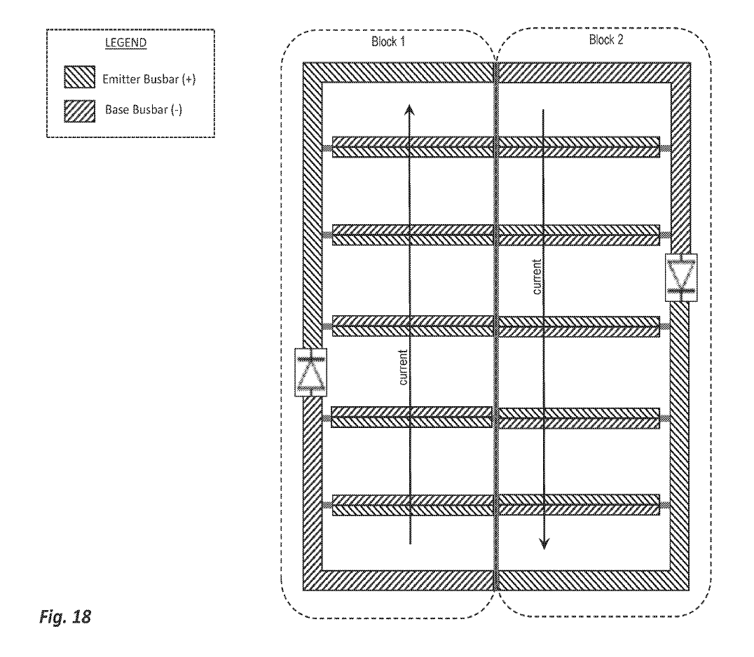

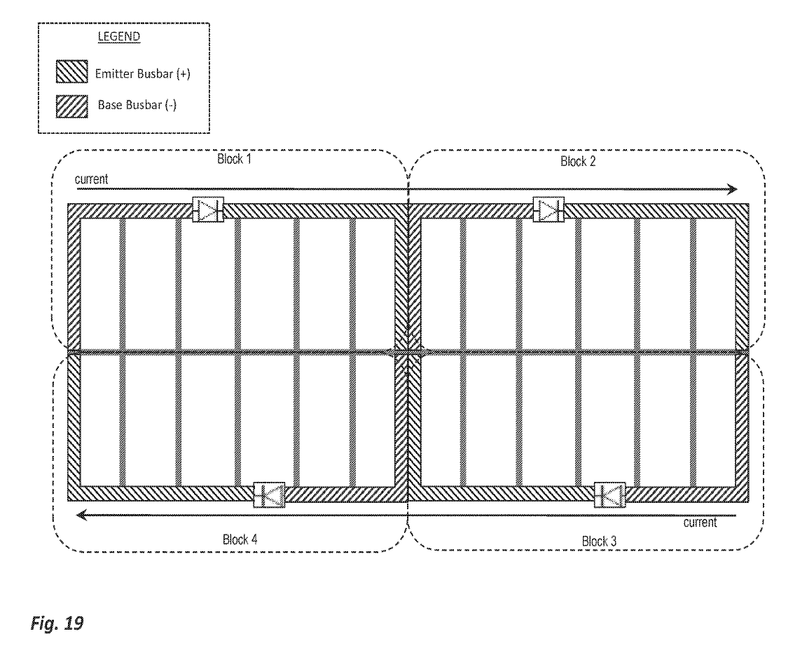

FIG. 18 is a drawing of the backside and second level busbar metallization of a 2×6 monolithically isled solar cell forming two shade management blocks, Block 1 and Block 2. FIG. 19 is a drawing of the backside and second level busbar metallization of two 2×6 monolithically isled solar cells, consistent with the 2×6 monolithically isled solar cell of FIG. 18, forming four shade management blocks, Block 1, Block 2, Block 3, and Block 4.

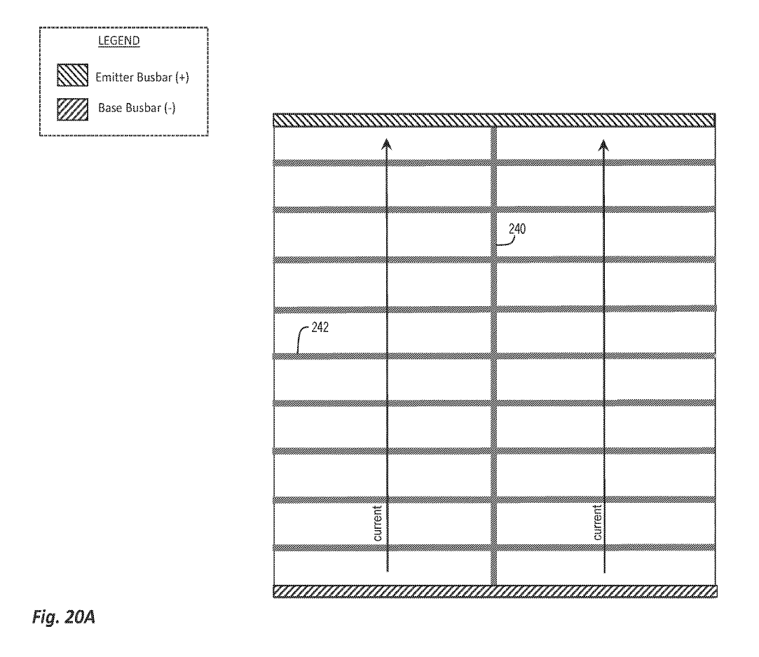

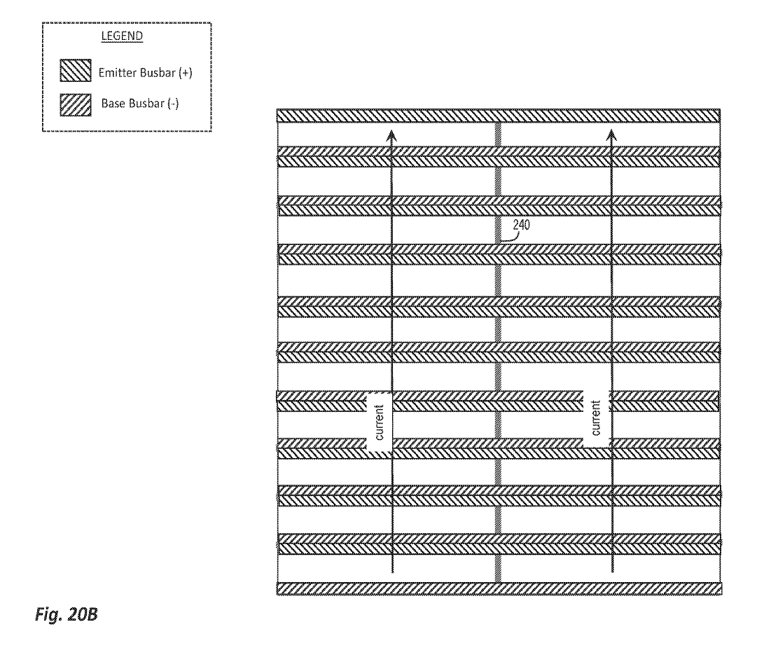

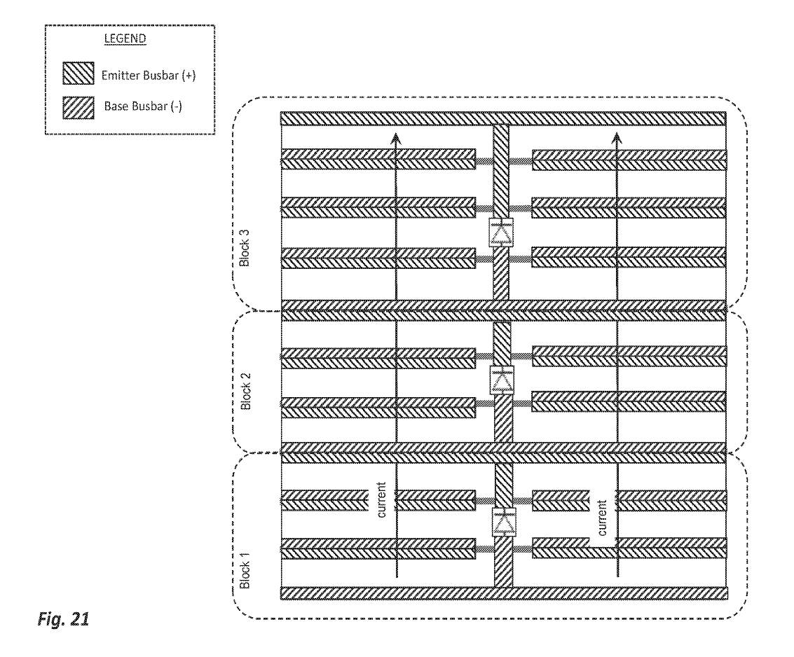

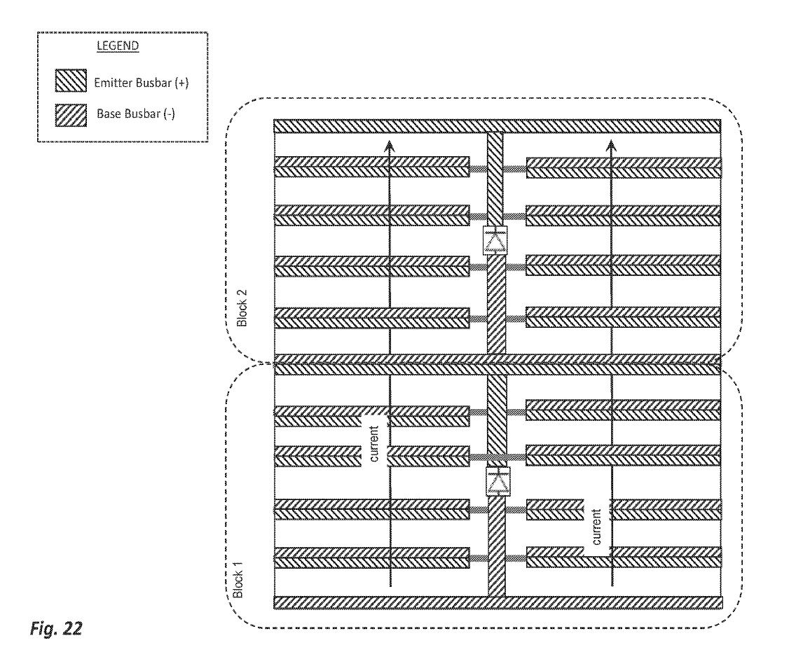

FIG. 20A is drawing of the backside and second level busbar metallization of a 1×10 monolithically isled solar cell having 10 isles (or regions or sub-cells) partitioned by nine horizontal x-axis electrical trench partition regions 242 and one optional vertical y-axis mechanical trench isolation region 240. FIG. 20B is drawing of the backside and second level busbar metallization of a 1×10 monolithically isled solar cell having 10 isles (or regions or sub-cells) showing solar isle base to emitter electrical connection. The optional vertical y-axis trench isolation region 240 of FIGS. 20A and 20B is a mechanical trench isolation region such that adjacent semiconductor isles separated by the vertical y-axis trench isolation region are electrically connected by same polarity second level metallization. FIG. 21 is drawing of the backside and second level busbar metallization of a 1×10 monolithically isled solar cell having 10 isles (or regions or sub-cells) and forming three shade management blocks, Block 1, Block 2, and Block 3. FIG. 22 is drawing of the backside and second level busbar metallization of a 1×10 monolithically isled solar cell having 10 isles (or regions or sub-cells) and forming two shade management blocks, Block 1 and Block 2.

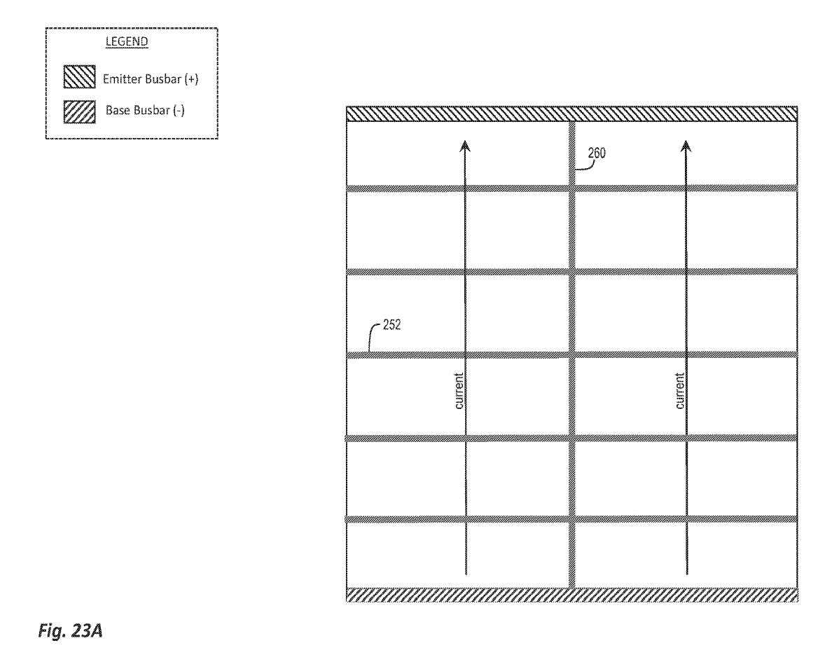

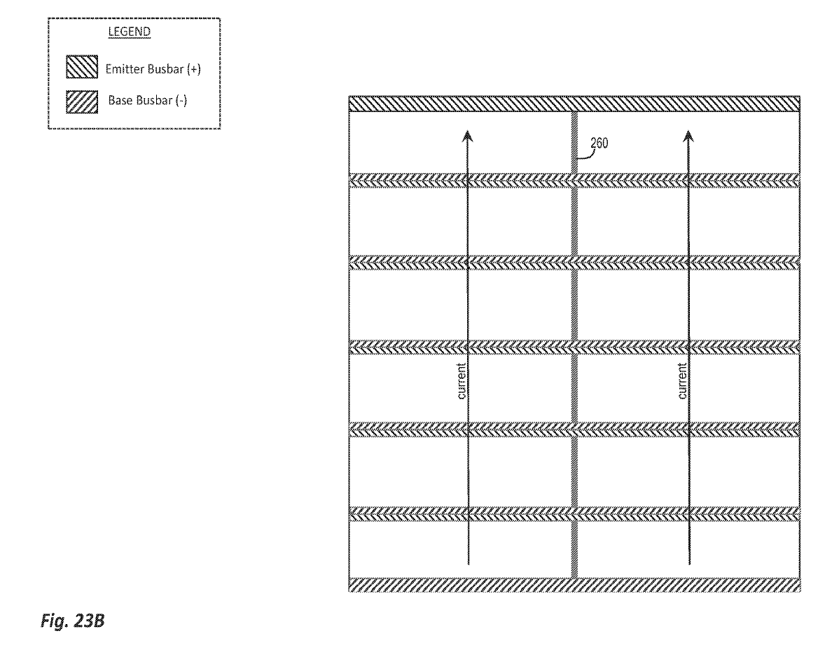

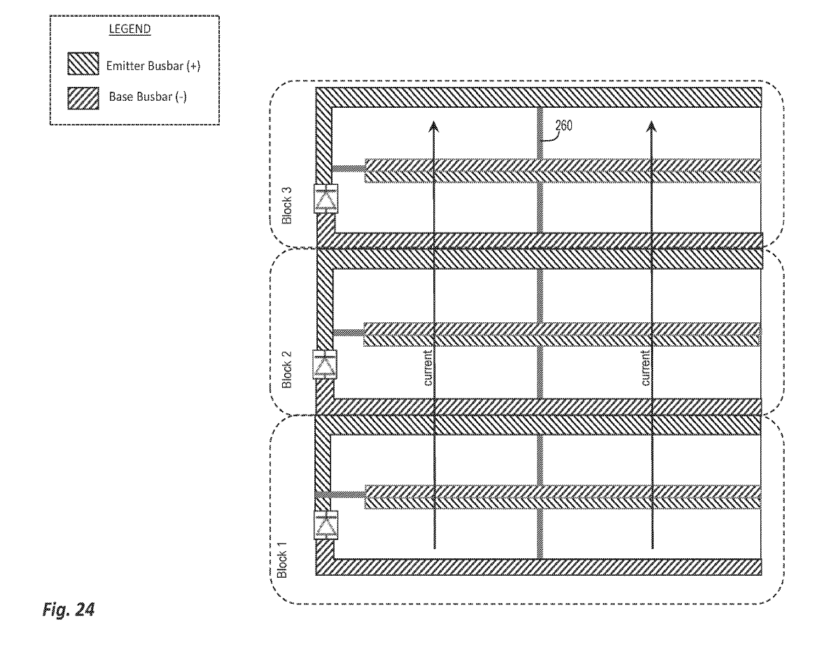

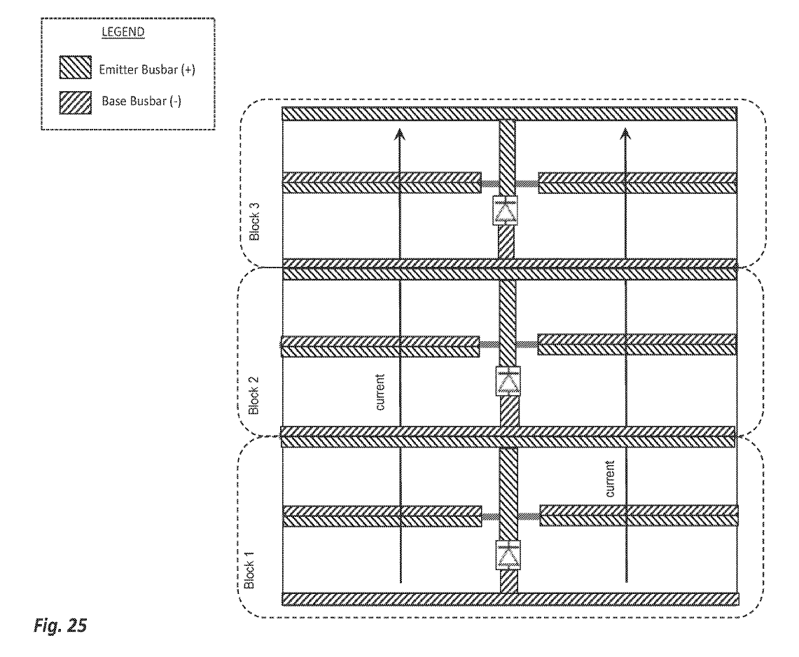

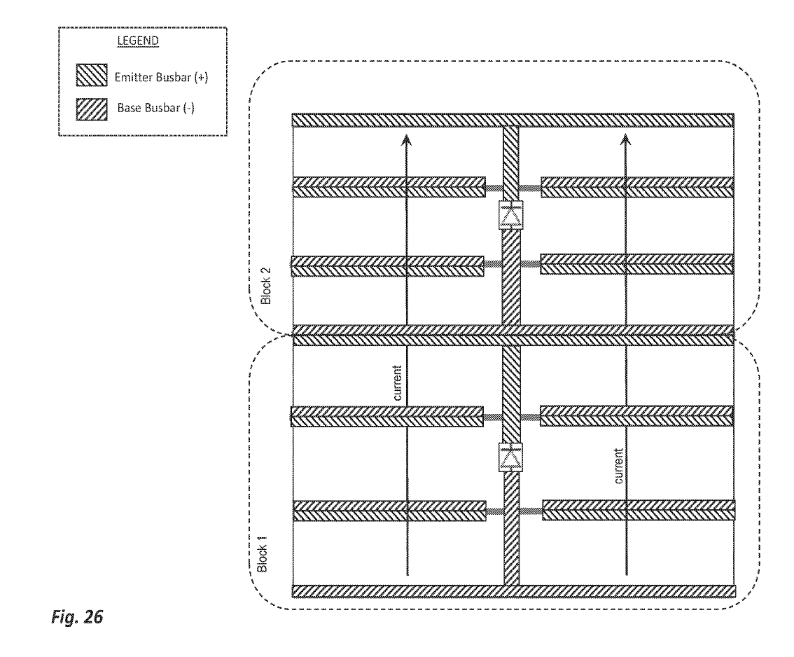

FIG. 23A is drawing of the backside and second level busbar metallization of a 1×6 monolithically isled solar cell having 6 isles (or regions or sub-cells) partitioned by five horizontal x-axis electrical trench partition regions 252 and optional vertical y-axis mechanical trench isolation region 260. FIG. 23B is drawing of the backside and second level busbar metallization of a 1×6 monolithically isled solar cell having 6 isles (or regions or sub-cells) showing solar isle base to emitter connection. The optional vertical y-axis trench isolation region 260 of FIGS. 23A and 23B is a mechanical trench isolation region such that adjacent semiconductor isles separated by the vertical y-axis trench isolation region are electrically connected by same polarity second level metallization. FIG. 24 is drawing of the backside and second level busbar metallization of a 1×6 monolithically isled solar cell having 6 isles (or regions or sub-cells) and forming three shade management blocks, Block 1, Block 2, and Block 3. FIG. 24 shows optional vertical y-axis trench isolation region 260. FIG. 25 is drawing of the backside and second level busbar metallization of a 1×6 monolithically isled solar cell having 6 isles (or regions or sub-cells) and forming three shade management blocks, Block 1, Block 2, and Block 3. FIG. 26 is drawing of the backside and second level busbar metallization of a 1×6 monolithically isled solar cell having 6 isles (or regions or sub-cells) and forming two shade management blocks, Block 1 and Block 2.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A photovoltaic solar structure, comprising:
at least two electrically connected solar cell regions forming a shade management block, said solar cell regions having at least:
a light receiving frontside and a passivated backside opposite said light receiving frontside; and
a first metallization over said passivated backside, said first metal having base and emitter metallization contacting base and emitter regions of said solar cell regions;
an electrically insulating backplane over said backsides of at least two solar cell regions, said electrically insulating backplane covering said first metallization of said at least two solar cell regions; and
a second metallization over said electrically insulating backplane and contacting said first metallization through said electrically insulating backplane, said second metallization having at least an opposite polarity electrical connection electrically connecting said at least two solar cell regions of said shade management block, said opposite polarity connection having positive and negative electrical polarities, and said opposite polarity electrical connection connected to a bypass diode.

2. The photovoltaic solar structure of claim 1, wherein said bypass diode is a bypass rectifying diode.

3. The photovoltaic solar structure of claim 1, wherein said bypass diode is a Schottky Barrier Rectifier.

4. The photovoltaic solar structure of claim 1, wherein said bypass diode is a PN junction diode.

5. The photovoltaic solar structure of claim 1, wherein said bypass diode is a transistor switch.

6. The photovoltaic solar structure of claim 1, further comprising a power optimizer connected to said bypass diode.

7. The photovoltaic solar structure of claim 1, wherein said opposite polarity connection is connected to an MPPT power optimizer.

8. The photovoltaic solar structure of claim 1, wherein said power optimizer is DC power optimizer

9. The photovoltaic solar structure of claim 1, wherein said electrically insulating backplane is a prepreg material.

10. The photovoltaic solar structure of claim 1, wherein at least one of said least two electrically connected two solar cell regions is made of at least two electrically connected solar cell regions.
